(19) United States
(12) Patent Application Publication
(10) Pub. No.: US 2025/0132283 A1
(43) Pub. Date: Apr. 24, 2025

(54) VERSATILE DUAL-LAYER TEMPORARY WAFER BONDING FOR HARSH PROCESSING CONDITIONS

(71) Applicant: Brewer Science, Inc., Rolla, MO (US)

(72) Inventors: Xin Li, Rolla, MO (US); Yongqing Grace Jiang, St Louis, MO (US); Ruimeng Zhang, Holmdel, NJ (US); Arthur O. Southard, St. James, MO (US); Luke M. Prenger, Rolla, MO (US)

(21) Appl. No.: 18/921,261

(22) Filed: Oct. 21, 2024

Related U.S. Application Data
(60) Provisional application No. 63/544,823, filed on Oct. 19, 2023.

(51) Int. Cl. H01L 23/00

(52) U.S. Cl. CPC H01L 24/73; H01L 24/13; H01L 24/29; H01L 2224/1357; H01L 2224/2919; H01L 2224/73104; H01L 2224/73204; H01L 2924/15311

(57) ABSTRACT

A dual-layer temporary bonding system for semiconductor manufacturing including first and second bonding layers is provided. The first bonding layer includes a bond line adhesion promoter that acts as a bond line adhesion promoter during the bonding process. The second bonding layer includes one or more functionalities that will react with the bond line adhesion promoter during the bonding process. The materials and methods of this system can provide increased, precisely controlled, bond line adhesion while at the same time also satisfying other desired performance criteria.

### CROSS-REFERENCE TO RELATED APPLICATIONS

The present application claims the priority benefit of U.S. Provisional Patent Application Ser. No. 63/544,823, filed Oct. 19, 2023, entitled VERSATILE DUAL-LAYER TEMPORARY WAFER BONDING FOR HARSH PROCESSING CONDITIONS, the entirety of which is incorporated by reference herein.

### BACKGROUND

### Field

The present disclosure relates generally to temporary wafer bonding materials and methods, and more particularly to dual-layer temporary wafer bonding materials and methods for semiconductor and microelectronics device fabrication.

### Description of Related Art

Homogeneous and heterogeneous integration for 2.5D and 3D integrated circuit, chip-to-wafer, chip-to-substrate, or wafer-to-wafer bonding are essential technologies. Fabrication techniques often require the thinning of device wafers having components used in a finished microelectronic product to the point at which it is difficult to handle the now-fragile ultrathin wafers without damage.

Temporary wafer bonding is used to temporarily bond a device wafer or microelectronic substrate to a carrier substrate (also referred to as a “carrier wafer” or simply “carrier”) for added physical support during processing. After bonding, the device wafer may be thinned (e.g., by backside grinding) typically to less than about 50 μm and/or processed to create through-silicon vias (TSV), redistribution layers, bond pads, and/or other circuit features using its backside. The carrier physically supports the fragile device wafer throughout this processing, which can entail repeated thermal cycling between ambient temperatures and high temperatures (e.g., >250° C.), mechanical shocks from wafer handling and transfer steps, and strong mechanical forces, such as may occur during backside grinding and/or chemical mechanical polishing (CMP). When this processing is complete, the device wafer is usually attached to a film frame and then separated (i.e., debonded) from the carrier wafer and cleaned, if necessary, for further manufacturing.

Most temporary bonding processes use one or two layers of bonding material between the device wafer and the carrier (i.e., single-layer or dual-layer). Depending on the process, the device wafer and carrier can be separated in various ways, such as chemical debonding, photonic debonding, thermal slide debonding, mechanical debonding, and laser debonding. In the case of a dual-layer system, two bonding material layers having distinct but cooperative characteristics are used. For example, in some cases a more easily cleaned or laser-ablatable bonding material is adjacent the device surface to facilitate clean separation of the bonding materials from the device wafer. Alternatively, a more robust bonding layer may be desirable adjacent the device wafer to protect features on the device wafer from physical damage. Preferences vary depending on the requirements of specific processes.

Many temporary bonding materials have been successful for a variety of semiconductor processes. However, advances in semiconductor technology now require exposure of bonded wafers to harsher conditions and present greater difficulties. For example, thermal stability over wide temperature ranges (e.g., up to 400° C.) is commonly required, along with a relatively low bonding temperature (e.g., around 25° C.) at the same time. Backside grinding and CMP under such harsh conditions and more extreme thermal cycling can cause delamination failures. Modern advanced packaging also commonly uses epoxy mold compound (EMC), such as is commonly used in fan-out wafer-level packaging (FOWLP). EMCs present adhesion difficulties and tend to warp easily, both of which exacerbate delamination problems. Efforts to address these problems through improvement of the bonding materials should not degrade the performance in other areas, including the requirements that the temporary bonding materials either leave no residue or be easily cleaned from the device wafer, that they provide good coverage and protection for topographical features on the device wafer (e.g., metal pillars/solder bumps) during thermal compression bonding and other harsh processes, and that they remain compatible with laser debonding and other debonding techniques. Moreover, the temporary bonding materials also need to withstand potential exposure to acids and/or bases, as well conditions associated with etching, metallization, and other processes that may be performed while the device wafer is bonded to the carrier.

Thus, despite substantial efforts there remains a need for improved temporary bonding materials and methods that address these problems.

### SUMMARY

The present disclosure is broadly concerned with a bonding method. The method comprises separating bonded first and second substrates, wherein the first substrate comprises a front surface, with a first bonding layer on the front surface. The second substrate comprises a first surface, with a second bonding layer on the first surface. The second bonding layer is in contact with the first bonding layer and at least one of the first and second bonding layers comprises a bond line adhesion promoter that is covalently bonded with a component present in the other of the first and second bonding layers.

In another embodiment, a bonding method comprising bonding a first bonding layer and a second bonding layer together is disclosed. During bonding, a bond line adhesion promoter that is present in at least one of the first and second bonding layers covalently bonds with a component present in the other of the first and second bonding layers. The first bonding layer is on a front surface of a first substrate, the second bonding layer is on a first surface of a second substrate, and at least one of the first and second substrates comprises a microelectronic substrate.

In a further embodiment a microelectronic structure comprising a first substrate and a second substrate is provided. The first substrate comprises a front surface, with a first bonding layer being on the front surface, and the second substrate comprises a first surface, with a second bonding layer on the first surface. At least one of the first and second bonding layers comprises a bond line adhesion promoter that is covalently bonded with a component present in the other of the first and second bonding layers.

### BRIEF DESCRIPTION OF THE DRAWINGS

FIG. 1 is a schematic (not to scale) depiction of one embodiment of a bonding method as described herein;

FIG. 2 is a fragmentary view with one of the features of FIG. 1, enlarged to show additional detail;

FIG. 3 is a fragmentary view with two of the features of FIG. 1, enlarged to show additional detail;

FIG. 4 is a schematic (not to scale) depiction of two alternative embodiments of the disclosed method;

FIG. 5 shows photographs of a bonded wafer pair from Example 5 viewed from the glass carrier side (a) after bonding and (b) after exposure to 300° C. for 15 minutes;

FIG. 6 shows photographs of a mechanically debonded wafer pair (left: silicon wafer with a thermoplastic material; right: glass carrier wafer with cured material);

FIG. 7 is a schematic of one embodiment of a razor blade test for bond line adhesion;

FIG. 8 is a bar graph showing results from the bond line adhesion test described in Example 6;

FIG. 9 is a graph showing the effects of promoter content on bond line adhesion and k value in materials from Example 7;

FIG. 10 shows scanning electron microscope (SEM) images of solder bumps on a topographical wafer coated by the material from Example 1: (a) cross-sectional view obtained by cutting the bump from center with focused ion beam (FIB) technique; (b) measurement of the top thickness in the high density area; and (c) measurement of the top thickness in the low density area;

FIG. 11 shows photographs of: (a) the material from Example 4 coated on an EMC wafer; (b) EMC wafer bonded with glass carrier; and (c) an EMC-glass wafer pair after 250° C. heat treatment for 15 minutes;

FIG. 12 is a graph showing the warpage of an EMC wafer at various stages of processing; and

FIG. 13 shows photographs of 25% allyl-containing Bond Line Adhesion Promoter B formulations where Bond Line Adhesion Promoter B was included at varying concentrations (Example 16).

### DETAILED DESCRIPTION

The present disclosure broadly provides dual-layer bonding materials and methods for semiconductor and other microelectronic device fabrication.

### First Bonding Composition

The first bonding composition is preferably a flowable composition selected to possess the components and properties described herein. Typical such first bonding compositions are preferably organic and will comprise a polymer(s) and/or oligomer(s) dissolved or dispersed in a solvent system. In some embodiments, the first bonding composition is a thermoplastic composition. In such embodiments, none of the components in the first bonding composition are crosslinkable with other components in the first bonding composition.

The polymers or oligomers are preferably thermoplastic and are typically chosen from polymers (including copolymers such as block copolymers) and/or oligomers of one or more of cyclic olefins (e.g., cyclic olefin copolymers (“COCs”), cyclic olefin polymers (“COPs”)), epoxies, acrylics, siloxanes, styrenics, vinyl halides, or vinyl esters. Typical polymers also include those chosen from one or more of polyamides, polyimides, polysulfones, polyethersulfones, polyolefins, polyisoprenes, polyurethanes, polyamide esters, polyimide esters, polyacetals, polyetheretherketones, polyetherimides, or combinations of the foregoing.

Suitable polymers and/or oligomers preferably have a weight average molecular weight of about 300 Daltons to about 100,000 Daltons, more preferably about 500 Daltons to about 50,000 Daltons, and even more preferably about 2,000 Daltons to about 20,000 Daltons, as determined by GC. The Mw/Mn (polydispersity, or PDI) is preferably from about 1.1 to about 4, more preferably about 1.5 to about 3, and even more preferably about 1.7 to about 2.3.

The polymer and/or oligomer component will preferably be present at a level of about 0.1% to about 50% by weight, more preferably about 2% to about 40% by weight, even more preferably about 7% to about 20% by weight, based upon the total weight of the first bonding composition taken as 100% by weight. Additionally or alternatively, the polymer and/or oligomer is present at about 5% to about 99.8% by weight, preferably about 30% to about 99.8% by weight, more preferably about 50% to about 90% by weight, even more preferably about 50% to about 80% by weight, and most preferably about 50% to about 70% by weight, based upon the total weight of all solids present in the first bonding composition taken as 100% by weight.

The solvent system can comprise one or more organic solvents, inorganic solvents, and/or water. Typical solids contents of the compositions will range from about 1% to about 60% by weight, and preferably from about 3% to about 40% by weight, based upon the total weight of the first bonding composition taken as 100% by weight, with the balance of the first bonding composition being solvent(s). Examples of solvents that can be used in the first bonding composition include those chosen from propylene glycol monomethyl ether acetate (“PGMEA”), propylene glycol methyl ether (“PGME”), propylene glycol ethyl ether (“PGEE”), propylene glycol n-propyl ether (“PnP”), ethyl lactate, cyclohexanone, gamma-butyrolactone (“GBL”), gamma-valerolactone (“GVL”), methyl isobutyl carbinol 3-methyl-1,5-pentanediol, 1,2-propylene glycol, 1,3-propylene glycol, ethylene glycol, cyclopentanone, or mixtures thereof.

The first bonding composition comprises oligomer(s) and/or polymer(s) that have respective glass transition temperatures (T_{g}) that are higher (and preferably at least about 5° C. higher, more preferably at least about 30° C. higher, and even more preferably at least about 50° C. higher) than the temperature that will be used during bonding (discussed further below). In one embodiment, the oligomer(s) and/or polymer(s) in the first bonding composition will have respective T_{g}s that are at least about 200° C., more preferably about 250° C. to about 500° C., even more preferably about 300° C. to about 400° C., and most preferably about 300° C. to about 350° C. T_{g} is determined by differential scanning calorimetry.

The first bonding composition will also include a bond line adhesion promoter. Preferred bond line adhesion promoters will be selected to react with one or more components present in the second bonding layer, discussed in more detail below. Suitable bond line adhesion promoters comprise a functional group, and preferably at least two such functional groups (i.e., they are at least difunctional), capable of reacting with one or more components present in the second bonding layer. Examples of such reactive functional groups include those chosen from imides (e.g., maleimides), vinyls (e.g., vinyl ethers, vinyl cyanides), allyls, hydroxys (including as part of a carboxylic acid), epoxides, silicon hydrides, esters, alkynes, amines, ketone, aldehydes, amides, thiols, or combinations of the foregoing.

The quantity of such reactive functional groups present on the bond line adhesion promoter will be varied depending on the desired adhesion strength, however, suitable quantities include having at least one (and preferably two) such functional groups on about 50% or more of the recurring monomeric units of the polymer and/or oligomer, preferably on about 75% or more of the recurring monomeric units, more preferably on about 90% or more of the recurring monomeric units, and most preferably on about 100% of the recurring monomeric units.

In some embodiments, the bond line adhesion promoter has a molar ratio of diepoxide-containing monomer to diol-containing monomer of about 1:0.25 to about 1:1.1, preferably about 1:0.5 to about 1:1, and more preferably about 1:0.95 to about 1:0.6.

In some embodiments, the previously described polymer and/or oligomer included in the first bonding composition will not include any of the functional group(s) present on the bond line adhesion promoter (i.e., the polymer and/or oligomer will not include any groups capable of reacting with one or more components present in the second bonding layer). In other embodiments, the polymer and/or oligomer may include a small amount of the same reactive functional group(s) present on the bond line adhesion promoter. For example, the polymer and/or oligomer may include less than about 10%, preferably less than about 5%, and more preferably less than about 1% of the quantity of reactive functional group(s) present on the bond line adhesion promoter.

Examples of preferred bismaleimides for use as the bond line adhesion promoter include those having the formula

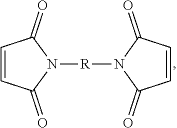

where R is chosen from substituted and unsubstituted alkyl groups, substituted and unsubstituted aromatic groups, or a combination of both. Preferred alkyl groups are C₁-C₁₈ groups, more preferably C₁-C₁₂ groups, and even more preferably C₁-C₆ groups. Preferred aromatic groups are C₁-C₆ aromatic groups, and R can include multiple aromatic groups of the same or a different type.

Suitable R groups include those selected from the group consisting of

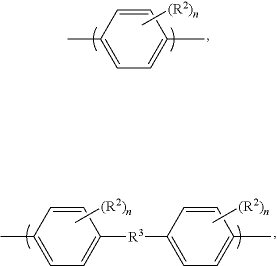

or combinations thereof, where:
   each R² is individually chosen from substituted and unsubstituted alkyl groups (preferably C₁-C₁₈, more preferably C₁-C₁₂, and even more preferably C₁-C₆) and —H;
   R³ is chosen from substituted and unsubstituted divalent alkyl groups (preferably C₁-C₁₈, more preferably C₁-C₁₂, and even more preferably C₁-C₆); and
   n is 1 to 4.

Examples of other suitable bond line adhesion promoters include one or more of

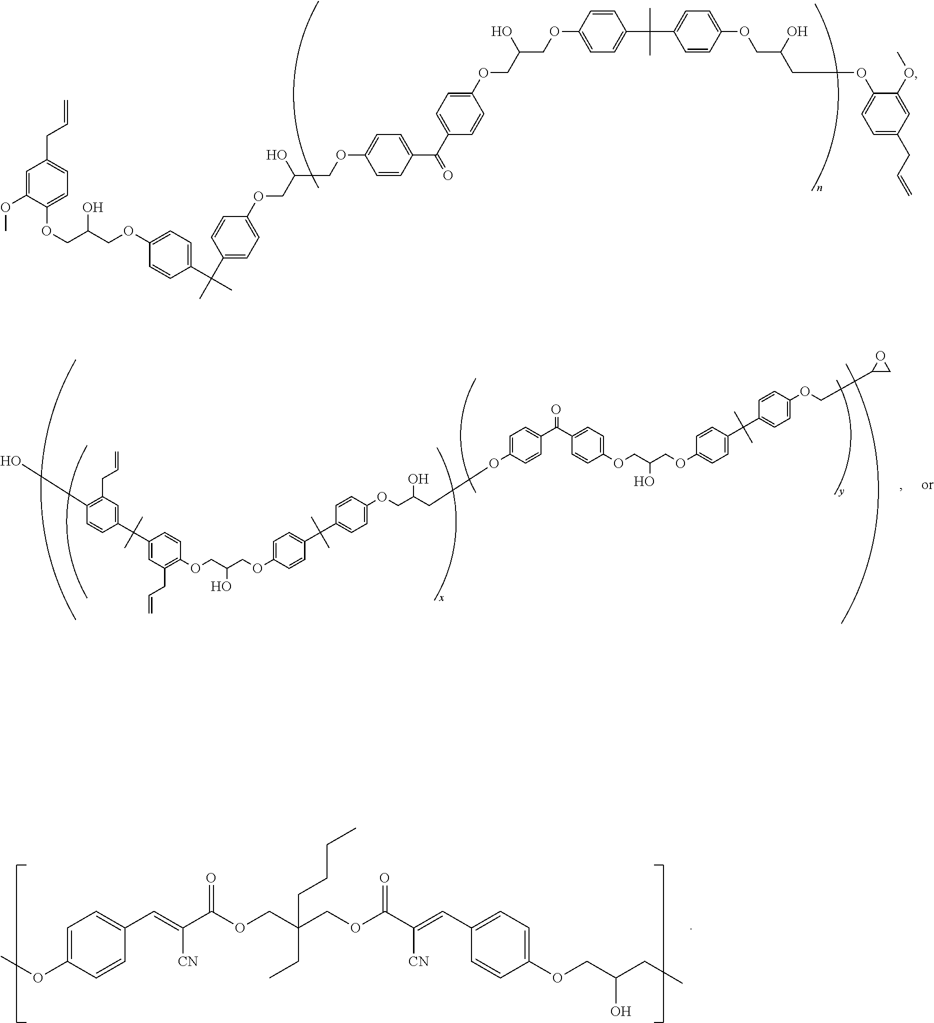

X is preferably about 1 to about 3, and y is preferably about 2 to about 4.

In one or more embodiments, the bond line adhesion promoter comprises monomers of diallylbisphenol A and dihydroxybenzophenone at a molar ratio of diallylbisphenol A to dihydroxybenzophenone of about 1:0.75 to about 1:4, and preferably about 1:1 to about 1:3.

In some embodiments, it is preferred that the bond line adhesion promoter is one that will not react with any components present in the first bonding composition.

The bond line adhesion promoter is preferably present in the first bonding composition at a level of about 0.01% to about 15% by weight, more preferably about 0.01% to about 8% by weight, even more preferably about 0.02% to about 4% by weight, based upon the total weight of the first bonding composition taken as 100% by weight. Additionally or alternatively, the bond line adhesion promoter is preferably present at about 1% to about 30% by weight, more preferably about 1.5% to about 15% by weight, and even more preferably about 2% to about 8% by weight, based upon the total weight of all solids present in the first bonding composition taken as 100% by weight.

The first bonding composition also preferably comprises an initiator for initiating the reaction between the bond line adhesion promoter and the second bonding layer, as described in more detail below. This initiator generates free radicals from the bond line adhesion promoter, preferably at temperatures higher than the baking temperature to which the first bonding composition will be subjected during first bonding layer formation. In some embodiments, the initiator doesn't initiate a reaction until it reaches a temperature of about 100° C. or higher, preferably of about 150° C. or higher, and more preferably about 180° C. or higher.

Examples of suitable initiators include those chosen from dicumyl peroxide, 2,2′-Azobis [2-(2-imidazolin-2-yl)-propane] dihydrochloride, tert-butyl hydroperoxide, cumene hydroperoxide, di-tert-butyl peroxide, benzoyl peroxide, ammonium persulfate or mixtures thereof. The initiator is preferably present in the first bonding composition at a level of about 0.001% to about 5% by weight, more preferably about 0.005% to about 3% by weight, and even more preferably about 0.01% to about 1% by weight, based upon the total weight of the bond line adhesion promoter taken as 100% by weight.

The first bonding compositions (and the layers they form) preferably have an adhesion strength sufficient to achieve a 5B rating in the ASTM D3359-23 cross hatch test when applied to a silicon substrate.

Some suitable starting compositions for use in forming first bonding layer are described in U.S. Pat. Nos. 9,496,164; 10,103,048; 10,968,348, 8,268,449, 7,935,780, and 8,092,628, as well as in US Published Patent Application No. 2022/0262755, the contents of each of which are hereby incorporated by reference. In preferred embodiments, a starting composition selected from one of the foregoing documents is a thermoplastic version (i.e., there would be no internal crosslinking of that composition during curing). By “starting composition,” it is meant that the bond line adhesion promoter (and possibly initiator) would need to be added to that starting composition, following the details provided above.

### Second Bonding Composition

The second bonding composition can be any conventional bonding composition capable of forming a strong adhesive bond with the first bonding layer. Typical such second bonding compositions are preferably organic and comprise a polymer(s) and/or oligomer(s) dissolved or dispersed in a solvent system. Preferably, the second bonding composition is a thermosetting composition.

The second bonding composition preferably has an adhesion strength of greater than about 50 psig (about 7 kPa), preferably about 80 psig (about 551 kPa) to about 250 psig (about 1,723 kPa), and more preferably about 100 psig (about 689 kPa) to about 150 psig (about 1,034 kPa), as determined by ASTM D4541/D7234.

Preferred second bonding compositions can be chemically crosslinked by heat, light, or other means. That is, these compositions suitably include photo- and/or thermally curable oligomer- and/or polymer-containing compositions (i.e., they are thermosetting), and preferably the types that produce little or no volatile by-products when cured. These include oligomer and/or polymer compositions containing reactive epoxy, acrylate, benzoxazine, maleimide, benzocyclobutene, and/or cyanate ester moieties. The reactive moieties can also include chalcone, stilbene, and/or other photodimerizable functional groups. Epoxy resin-containing compositions that are cured with the aid of a photoacid generator (“PAG”) or thermal acid generator (“TAG”) are especially useful for practicing this embodiment. In some embodiments, the oligomer and/or polymer present in the second bonding composition includes at least two such reactive functional groups or moieties, and preferably at least two per recurring monomer. The process for applying and drying the thermosetting composition prior to the bonding process should minimize, and preferably avoid, causing the composition to crosslink, so that it will remain flowable during the bonding process and allow a void-free bond line to be formed.

The second bonding composition preferably includes at least one moiety or functional group capable of bonding with the bond line adhesion promoter present in the first bonding composition, as described previously. For example, if the bond line adhesion promoter in the first bonding composition is a bismaleimide, the thermoset bonding material suitably includes a reactive vinyl group or other bonding site accessible to react with the bond line adhesion promoter after the two bonding layers are brought together during the bonding process. Depending on the specific bond line adhesion promoter included in the first bonding composition, the functional groups present on the oligomer and/or polymer in the second bonding composition for reacting with the bond line adhesion promoter can be a functional group added for the specific purpose of allowing crosslinking or reacting with the bond line adhesion promoter. Alternatively or additionally, suitable crosslinking or reaction sites may already be available on the oligomers and/or polymers without including a moiety or functional group for this specific purpose. Examples of functional groups that can be included on the oligomer and/or polymer present in the second bonding composition include one or more chosen from of imides (e.g., maleimides), vinyls (e.g., vinyl ethers, vinyl cyanides), allyls, hydroxys (including as part of a carboxylic acid), epoxides, silicon hydrides, esters, alkynes, amines, ketone, aldehydes, amides, thiols, or combinations of the foregoing.

Examples of suitable oligomers and polymers that could include the above-described functional groups include oligomers and/or polymers comprising cyclic olefins, epoxies, acrylics, silicones, styrenics, vinyl halides, vinyl esters, polyamides, polyimides, polysulfones, polyethersulfones, polyolefin rubbers, polyurethanes, ethylene-propylene rubbers, polyamide esters, polyimide esters, polyacetals, polyvinyl butyral, or combinations of the foregoing.

The polymer and/or oligomer component is preferably present at a level of about 20% to about 85% by weight, more preferably about 25% to about 80% by weight, even more preferably about 30% to about 75% by weight, based upon the total weight of the second bonding composition taken as 100% by weight. Additionally or alternatively, the polymer and/or oligomer is preferably present at about 85% to about 100% by weight, more preferably about 90% to about 100% by weight, based upon the total weight of all solids present in the second bonding composition taken as 100% by weight.

Suitable polymers and/or oligomers preferably have a weight average molecular weight of about 300 Daltons to about 1,500,000 Daltons, more preferably about 500 Daltons to about 1,000,000 Daltons, and even more preferably about 2,000 Daltons to about 750,000 Daltons. The Mw/Mn (polydispersity, or PDI) is preferably from about 1.1 to about 15, more preferably about 1.5 to about 9, and even more preferably about 1.7 to about 5.

The second bonding composition comprises oligomer(s) and/or polymer(s) that have respective glass transition temperatures (T_{g}) that are lower (and preferably at least about 5° C. lower, more preferably at least about 30° C. lower, and even more preferably at least about 50° C. lower) than the temperature that will be used during bonding (discussed further below). In one embodiment, the oligomer(s) and/or polymer(s) in the second bonding composition have respective T_{g}s that are at least about 200° C., more preferably about 250° C. to about 500° C., even more preferably about 300° C. to about 400° C., and most preferably about 300° C. to about 350° C.

The solvent system included in the second bonding composition can comprise one or more organic solvents, inorganic solvents, and/or water. Typical solids contents of the compositions range from about 1% to about 60% by weight, and preferably from about 3% to about 40% by weight, based upon the total weight of the first bonding composition taken as 100% by weight, with the balance of the first bonding composition being solvent(s). Examples of solvents that can be used in the first bonding composition include those chosen from PGMEA, PGME, PGEE, PnP, ethyl lactate, mesitylene, toluene, xylene, cyclohexanone, GBL, GVL, methyl isobutyl carbinol 3-methyl-1,5-pentanediol, 1,2-propylene glycol, 1,3-propylene glycol, ethylene glycol, cyclopentanone, or mixtures thereof.

In some embodiments, the second bonding composition is self-crosslinking. Additionally or alternatively, the second bonding composition includes a crosslinking agent for internally crosslinking the second bonding layer during its formation (discussed below). That is, the second bonding composition optionally comprises about 0.1% to about 20% by weight crosslinking agent, more preferably about 0.5% to about 10% by weight crosslinking agent, and even more preferably about 1% to about 5% by weight crosslinking agent, based upon the total weight of the polymer and/or oligomer taken as 100% by weight.

In some embodiments, a catalyst such as a crosslinking catalyst may be included in the second bonding composition. Suitable catalysts include those chosen from thermal acid generators (TAGs), such as a quaternary ammonium blocked triflic acid thermal acid generator (e.g., TAG2689 from King Industries and TAG2690 from King Industries), acids (such as nitric acid or maleic acid), benzyltriethylammonium chloride (“BTEAC”), ethyltriphenylphosphonium bromide, tetrabutylphosphonium bromide, or combinations thereof. The catalyst is preferably present in the second bonding composition at levels of about 0.01% to about 10% by weight, and more preferably about 0.1% to about 5% by weight, based upon the total weight of the polymer and/or oligomer taken as 100% by weight.

A suitable commercially available material for use as second bonding composition is sold under the name BrewerBOND® C1301 (Brewer Science, Inc., Rolla, MO). Other suitable compositions include any thermosetting compositions described in U.S. Patent Application Publication No. 2021/0033975, and U.S. Pat. Nos. 9,496,164, 10,103,048, 10,968,348, 11,610,801, each incorporated by reference herein.

### Bonding and Debonding Methods

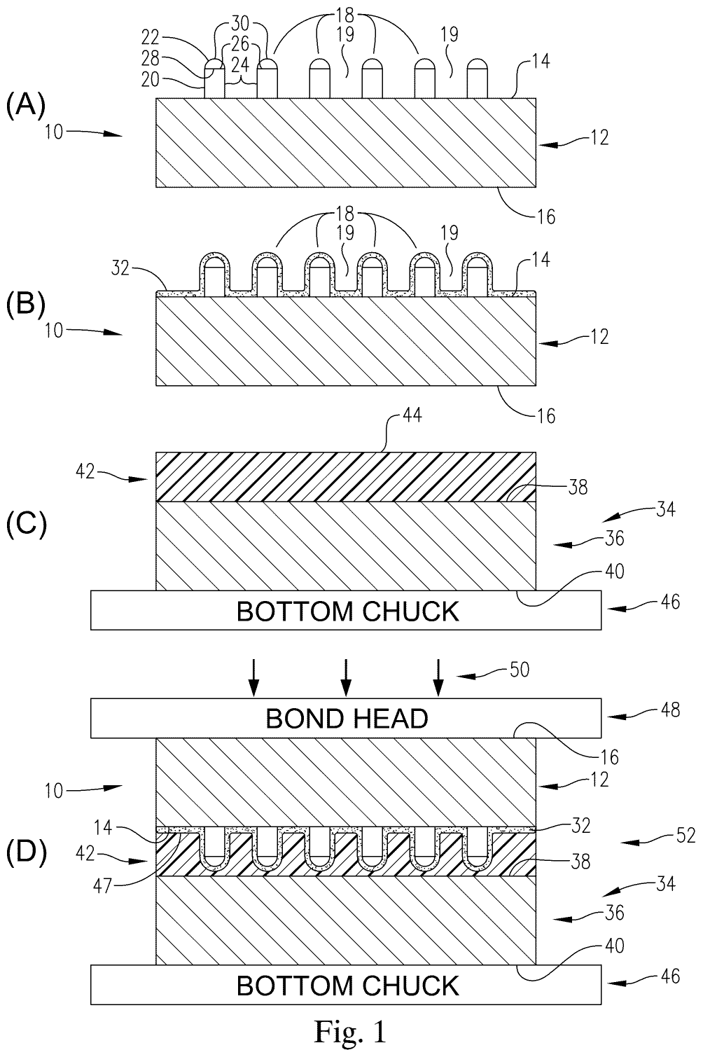

In more detail and referring to FIG. 1(A) (not to scale), a precursor structure 10 is depicted in a schematic and cross-sectional view. Structure 10 includes a first substrate 12, which has a front surface 14 and a back surface 16. Although first substrate 12 can be of any shape, it is typically circular, rectangular, or oblong in shape. In one embodiment, first substrate 12 can be a silicon or glass wafer, such as a glass panel substrate of the type used in chip-to-substrate applications. In another embodiment, first substrate 12 is a device wafer, and front surface 14 is preferably a device surface that includes a plurality of features 18 and areas 19 therebetween. While the illustrated embodiment only depicts features 18, it will be appreciated that device surfaces can comprise an array of devices such as those chosen from integrated circuits, MEMS, microsensors, power semiconductors, light-emitting diodes, photonic circuits, interposers, embedded passive devices, and/or other microdevices fabricated on silicon and other semiconducting materials such as silicon-germanium, gallium arsenide, gallium nitride, aluminum gallium arsenide, aluminum indium gallium phosphide, and/or indium gallium phosphide. These device surfaces commonly comprise features formed from one or more of the following materials: silicon, polysilicon, silicon dioxide, silicon (oxy) nitride, metals (e.g., copper, aluminum, gold, tungsten, tantalum), low k dielectrics, polymer dielectrics, or various metal nitrides and/or silicides. Such device surfaces can also include features chosen from one or more of: solder bumps; metal posts; metal pillars; and structures formed from a material selected from the group consisting of silicon, polysilicon, silicon dioxide, silicon (oxy) nitride, metal (e.g., copper, aluminum, gold, tungsten, tantalum), low k dielectrics, polymer dielectrics, metal nitrides, and metal silicides.

Moreover, in some embodiments the first substrate 12 is a heterogeneous substrate having a bonding surface made of different materials having different properties. For example, the first substrate 12 can be a reconstituted wafer formed by integrating an array of separated semiconductor dies using an epoxy mold compound, which results in a bonding surface having materials having substantially different adhesion characteristics and also substantially different coefficients of thermal expansion.

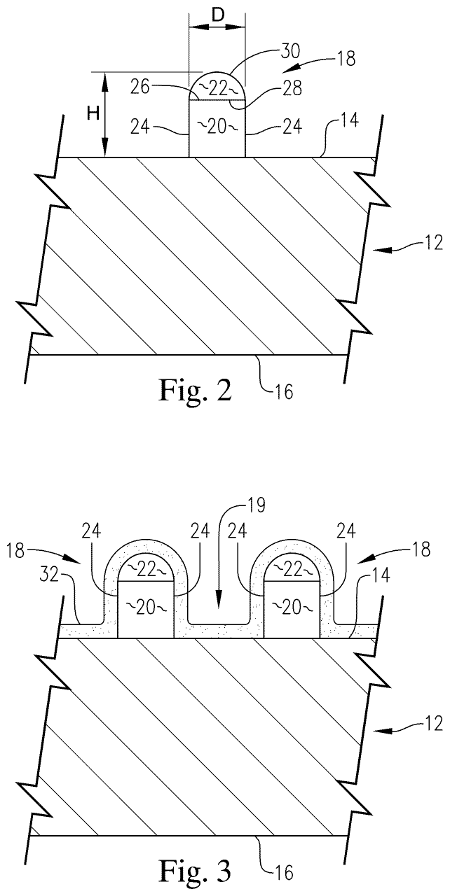

In the embodiment illustrated, features 18 each comprise a metal pillar 20 and a solder bump or ball 22. FIG. 2 depicts an enlarged view of a feature 18. Each metal pillar 20 extends from upper surface 14 and has respective sidewalls 24 and respective upper surfaces 26. Respective solder balls 22 are positioned on upper surfaces 26. Each solder ball 22 has a contact surface 28 that is in contact with metal pillar upper surface 26. Additionally, each solder ball 22 has a curved outer surface 30 (an “upper” curved surface in the embodiment depicted) that is not in contact with upper surface 26. Metal pillars 20 can be formed of any conventionally used material, including copper, gold, and/or aluminum.

It will be appreciated that solder bumps or balls 22 can be made of any number of materials, depending upon the particular application, design, and other needs. Bumps (e.g., half-spheres on top of a pillar) or balls 22 typically comprise one or more metals or metal alloys. For example, the bumps or balls 22 may be formed from one or more of Sn, Ag, Ni, Cu, Ti, W, Au, Pb, Bi, Zn, Cd, or In, in alloy or non-alloy form. Typical alloys that are used include those chosen from one or more of SnAg, SnPb, SnInAg, or AuSn. In some instances, solder bumps or balls can comprise a core of a first material (e.g., polymeric, metal, metal alloy) and one or more layers of the same or different metals and/or metal alloys surrounding the core.

The solder bumps or balls 22 can have a wide range of sizes, depending on the particular application and end-use needs but typical dimensions are about 10 μm to about 120 μm, preferably about 20 μm to about 90 μm and more preferably about 30 μm to about 50 μm. These dimensions can refer to either the diameter of the solder ball prior to use (i.e., “as-purchased) or to the maximum surface-to-surface dimension presented by the solder ball or bump after application. “D” in FIG. 2 shows the maximum dimension of solder bump 22 of the illustrated embodiment, while “H” refers to the combined total of the solder ball 22 height and the pillar 20 height.

Referring to FIG. 1(B), a first bonding composition as described previously is applied to front surface 14 of first substrate 12 to form a first bonding layer 32. The first bonding composition can be applied by any known application method, such as spin coating, spray coating, ink-jet printing, dip coating, roller coating, slot coating, die coating, screen printing, draw-down coating, jetting, or spray coating. A preferred method involves spin-coating the composition at speeds of about 500 rpm to about 3,000 rpm, and preferably about 1,000 rpm to about 1,500 rpm, for a time period of about 20 seconds to about 60 seconds, and preferably about 30 seconds to about 40 seconds. Alternatively, the composition can be applied by other methods. After the composition is applied, it is preferably heated to a temperature of about 40° C. to about 250° C., and more preferably about 60° C. to about 220° C., for time periods of about 1 second to about 6 minutes, and more preferably about 60 seconds to about 4 minutes, thus forming first bonding layer 32. In some embodiments, it is preferable to subject the layer to a multi-stage bake process, depending upon the composition utilized. In one or more embodiments, it is preferred that the first bonding layer 32 undergoes no crosslinking during this process.

The formed first bonding layer 32 preferably has a T_{g} that is higher (preferably at least about 5° C. higher, more preferably at least about 30° C. higher, and even more preferably at least about 50° C. higher) than the temperature that will be used during bonding (discussed further below). In one embodiment, the formed first bonding layer 32 has a T_{g} of at least about 200° C., more preferably about 250° C. to about 500° C., even more preferably about 300° C. to about 400° C., and most preferably about 300° C. to about 350° C. Furthermore, the formed first bonding layer 32 preferably has a Young's modulus of about 0.5 GPa to about 3 GPa, more preferably about 1 GPa to about 2.5 GPa, and even more preferably about 1.8 GPa to 2.2 GPa at a temperature of about 250° C. as determined by DMA.

Additionally, and as illustrated in FIG. 1(B), first bonding layer 32 forms a substantially continuous, hard coating on front surface 14 of first substrate 12 (including at the areas 19, which are free of features 18 and/or solder balls 22), sidewalls 24 of metal pillars 20, and curved surfaces 30 of solder balls 22, preferably with no intervening layer or other material between first bonding layer 32 and surface 14, sidewalls 24, or curved surfaces 30.

In the embodiment depicted in FIG. 1(B), first bonding layer 32 is a conformal layer. “Conformal” is broadly intended to refer to the fact that a layer generally follows the underlying topography (i.e., it does not planarize over the features/topography to create a planar or substantially planar surface). There can be a large degree of thickness variation in a layer that is still considered conformal, provided that this layer does not create a planar or flat surface (i.e., it does not remove surface topologies) but instead generally follows the contour of that topography.

The degree of thickness variation of a conformal layer can vary, depending on the embodiment. In one embodiment, first bonding layer 32 may have an average thickness (measured at five locations) of about 0.1 μm to about 20 μm, 0.2 μm to about 10 μm, and preferably about 0.5 μm to about 5 μm. Thicknesses as used herein can be measured using any film thickness measurement tool, with one preferred tool being an infrared interferometer, such as those sold by SUSS Microtec or Foothill.

In one embodiment, first bonding layer 32 may have a substantially uniform thickness on and across areas 19 of surface 14 as well as on and across sidewalls 24 and curved surfaces 30 of features 18, as schematically depicted in FIG. 3, thus “conforming” to the underlying topography. That is, in this embodiment the first bonding layer 32 has a relatively low total thickness variation (“TTV”), meaning that the thickest and thinnest points of first bonding layer 32 are not dramatically different from one another. Preferably, the TTV of first bonding layer 32 is less than about 90% of the total average thickness, more preferably less than about 60% of the total average thickness, even more preferably less than about 40% of the total average thickness, and most preferably less than about 20% of the total average thickness. For example, if the average thickness of the first bonding layer 32 is about 10 μm, a TTV of less than about 20% will be about 2 μm.

TTV is preferably calculated by measuring the thickness at a number of points or locations on first bonding layer 32, preferably at about 50 points, more preferably at about 100 points, and even more preferably at about 1,000 points. The difference between the highest and lowest thickness measurements obtained at these points is designated the TTV measurement for that particular first bonding layer 32. In some TTV measurement instances, edge exclusion or outliers may be removed from the calculation. In those cases, the number of included measurements is indicated by a percentage. For example, if a TTV is given at 97% inclusion, then 3% of the highest and lowest measurements are excluded, with the 3% split equally between the highest and lowest (i.e., 1.5% each). Preferably, the TTV ranges noted above are achieved using about 95% to about 100% of the measurements, more preferably about 97% to about 100% of the measurements, and even more preferably about 100% of the measurements.

In one embodiment, first bonding layer 32 is still conformal in that it generally follows the underlying topography (i.e., it does not planarize over the features/topography to create a planar surface), but the TTV of first bonding layer 32 is much more relaxed than the previously described embodiment. However, in spite of being relaxed, first bonding layer 32 is not a planarizing layer. In these instances, the first bonding layer 32 can have a thickness at its thickest point that is about 2 to about 15 times, preferably about 2 to about 10 times, and more preferably about 3 to about 8 times thicker than first bonding layer 32's thickness at its thinnest point. In these embodiment, the thicker portions of first bonding layer 32 are generally found in areas 19 (i.e., areas between pillars, solder bumps, and/or other features or structures), while the thinner portions are generally found on the top and/or sides of the pillars, solder bumps, and/or other features (e.g., on curved surfaces 30 and/or on sidewalls 24).

In some embodiments, the first bonding layer 32 can be planarizing (not shown).

Regardless of the embodiment, first bonding layer 32 is preferably continuous across its entirety. That is, it is preferred that all of first bonding layer 32 continues across the features/topography uninterrupted (i.e., no “breaks” in the coating of first bonding layer 32), as shown in the accompanying Figures.

Referring to FIG. 1(C), a second precursor structure 34 is depicted, also in a schematic and cross-sectional view. Second precursor structure 34 includes a second substrate 36. In this embodiment, second substrate 36 is a carrier wafer and has a first or carrier surface 38 and a back surface 40. Although second substrate 36 can be any shape, it is typically circular in shape and sized similarly to first substrate 12. In embodiments where second substrate 36 is a carrier wafer, preferred such carrier wafers include those comprising silicon, sapphire, quartz, metals (e.g., aluminum, copper, steel), various glasses (e.g., Corning Gorilla Glass), and/or ceramics substrates/wafers. In some embodiments, second substrate 36 is a carrier wafer that is selected to be transparent, particularly to laser energy. Suitable carriers preferably have a similar coefficient of thermal expansion (CTE) to the first substrate 12.

First surface 38 of second substrate 36 includes a second bonding layer 42 formed thereon. Second bonding layer 42 has a bonding surface 44 remote from second substrate 36. Preferably, second bonding layer 42 is formed directly on the front surface 38 (i.e., without any intermediate layers between the second bonding layer 42 and second substrate 36).

A second bonding composition as described previously can be applied to form second bonding layer 42 by using any conventional application method, including spin coating, ink-jet printing, dip coating, roller coating, slot coating, die coating, screen printing, draw-down coating, or spray coating. Alternatively, the coatings may be formed into free-standing films before application to the carrier surface 38. One preferred method involves spin coating the second bonding composition at speeds of about 200 rpm to about 5,000 rpm, and preferably about 500 rpm to about 3,000 rpm, for a time period of about 5 seconds to about 120 seconds, and preferably about 30 seconds to about 90 seconds.

After the second bonding composition is applied to carrier surface 38, it is preferably heated to a temperature of about 50° C. to about 250° C., and more preferably about 80° C. to about 220° C., for time periods of about 60 seconds to about 8 minutes, and preferably about 90 seconds to about 6 minutes. In preferred embodiments, second bonding composition will crosslink during this heating, so that the resulting second bonding layer 42 is a crosslinked layer, i.e., second bonding layer 42 is a thermoset layer.

In one or more embodiments, the above application and bake process can be repeated with a further aliquot of the second bonding composition so that the second bonding layer 42 is “built” and includes two or more sublayers formed in two or more steps.

In some embodiments, it is preferable to subject the second bonding layer 42 to a multi-stage bake process, depending upon the second bonding composition utilized.

Additionally, in some embodiments, UV or visible light can be used to carry out the curing process. The UV light activates an initiator in the second bonding layer 42, thus producing radicals that cause curing of second bonding layer 42. Typical wavelengths for this curing are from about 200 nm to about 500 nm, and preferably about 300 nm to about 400 nm.

Second bonding layer 42 preferably has a softening point that is at least about 40° C., preferably about 50° C. to about 200° C., and more preferably about 60° C. to about 150° C. The thickness of second bonding layer 42 is preferably about 1 μm to about 200 μm, more preferably about 10 μm to about 150 μm, and even more preferably about 20 μm to about 120 μm. Additionally, the formed second bonding layer 42 suitably has a T_{g} that is lower (preferably at least about 5° C. lower, more preferably at least about 30° C. lower, and even more preferably at least about 50° C. lower) than the temperature that will be used during bonding (discussed further below). In one embodiment, the formed second bonding layer 42 suitably has a T_{g} of at least about 200° C., more preferably about 250° C. to about 500° C., even more preferably about 300° C. to about 400° C., and most preferably about 300° C. to about 350° C. Furthermore, the second bonding layer 42 preferably has a storage modulus in the range of about 0.1 MPa to about 60 MPa, more preferably about 0.5 MPa to about 20 MPa at a temperature of about 250° C.

Referring to FIG. 1(D), second precursor structure 34 is supported on a bottom chuck 46, while a bond head 48 applies a downward pressure 50 against back surface 16 of first substrate 12, causing structures 10 and 34 to be pressed together in a face-to-face relationship. Thus, bonding surface 44 of second bonding layer 42 is in contact with front surface 14 (including areas 19 and features 18) of first substrate 12. While pressing, sufficient pressure and heat are applied for a sufficient amount of time so as to effect bonding of the two structures 10 and 34 together to form a bonded stack 52.

This bonding process initiates a reaction between the bond line adhesion promoter in the first bonding layer 32 and a component present in the second bonding layer 42, with this reaction preferably being a covalent bonding reaction. In some embodiments, this reaction is a free radical reaction initiated by an initiator present in the first bonding layer 32. The initiator causes the bond line adhesion promoter to form free radicals that then react with the component in the second bonding layer 42, with that component typically being the previously described polymer and/or oligomer present in the second bonding layer 42. One example of this reaction is depicted in Scheme A, where the bond line adhesion promoter is a bismaleimide, the initiator is generically depicted, first bonding layer 32 is referred to as the “thermoplastic layer,” and second bonding layer 42 is referred to as the “curable layer.”

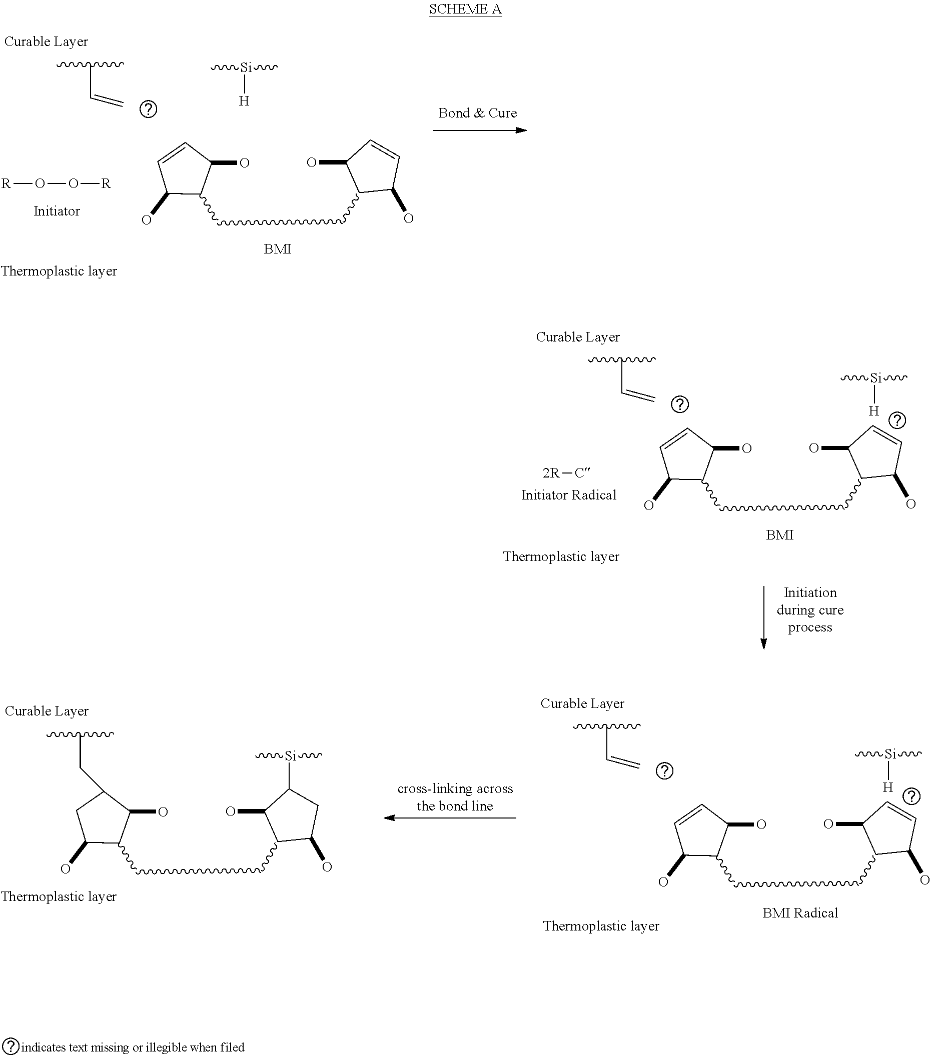

It will be appreciated that this reaction results in a continuous, void-free bonding interface or bond line 47 being formed between first bonding layer 32 and second bonding layer 42, as depicted in FIG. 1(D). This can be achieved by the selection of the bond line adhesion promoter and/or compositions used to form first bonding layer 32 and/or second bonding layer 42.

The bonding parameters can vary depending upon the type of compositions from which first bonding layer 32 and second bonding layer 42 are formed, but typical bonding temperatures range from about 20° C. to about 200° C., and preferably from about 25° C. to about 100° C., with typical pressures ranging from no pressure (i.e., simply using gravity bonding with no additional force being applied by the bonder), to pressure being applied by the bonder at levels of about 1 N to about 5,000 N, and preferably about 100 N to about 3,000 N, for a time period of about 10 seconds to about 10 minutes, and more preferably about 1 minutes to about 4 minutes.

In some embodiments, UV or visible light can be used to bond first bonding layer 32 and second bonding layer 42. Typical bonding wavelengths are from about 200 nm to about 500 nm, and preferably about 300 nm to about 400 nm.

In some embodiments, a post-bond, curing bake can be applied to complete the curing process of second bonding layer 42. The post-bond, curing bake is typically conducted at about 100° C. to about 275° C., and preferably about 150° C. to 225° C. for about 1 second to about 60 minutes, and more preferably for about 5 minutes to about 30 minutes. This post-bond, curing bake can also be carried out in two stages, which typically involves a first stage at a lower temperature within the above temperature ranges and for a shorter period of time within the above bake time ranges, followed by a second stage at a higher temperature and for a longer time than the first stage. For example, the first stage might be carried out at about 100° C. to about 200° C. (preferably about 150° C. to 185° C.) for about 30 seconds to about 10 minutes (preferably about 1 minute to about 5 minutes), and/or the second stage might be carried out at about 200° C. to about 250° C. (preferably about 210° C. to 230° C.) for about 5 minutes to about 20 minutes (preferably about 5 minutes to about 15 minutes).

In some embodiments, UV or visible light can be used to carry out a post-bond cure. The UV light activates an initiator in the second bonding layer 42, thus producing radicals that cause curing of second bonding layer 42. Typical wavelengths for this post-bond cure are from about 200 nm to about 500 nm, and preferably about 300 nm to about 400 nm.

Bond line 47 has a bond line adhesion (γ) of about 10 mJ/cm² to about 10,000 mJ/cm², preferably about 50 mJ/cm² to about 8,000 mJ/cm², and more preferably about 80 mJ/cm² to about 5,000 mJ/cm². In some embodiments, bond line 47 has a bond line adhesion (Y) of about 350 mJ/cm² or greater, preferably about 1,000 mJ/cm² or greater, more preferably about 1,500 mJ/cm² or greater, and even more preferably about 2,000 mJ/cm² or greater. In other embodiments, bond line 47 has a bond line adhesion (Y) of about 1,000 mJ/cm² to about 5,000 mJ/cm², preferably about 1,500 mJ/cm² to about 5,000 mJ/cm², more preferably about 2,000 mJ/cm² to about 5,000 mJ/cm², and more preferably about 2,000 mJ/cm² to about 4,000 mJ/cm². Bond line adhesion (Y) is determined as described in Example 6.

At this stage, the first substrate can be safely handled and subjected to further processes that might otherwise have damaged the front surface 14 and/or features 18 of the first substrate 12 were it not bonded to second substrate 36. Thus, the structure 10 (as part of stack 52) can now safely be subjected to backside processing such as back-grinding, redistribution layer (RDL) formation, pad formation, chemical-mechanical polishing (“CMP”), etching, metallizing, dielectric deposition, patterning (e.g., photolithography, via etching), passivation, and/or annealing, without separation of substrates 12 and 36 occurring, and without infiltration of any chemistries encountered during these subsequent processing steps. Not only can first bonding layer 32 and second bonding layer 42 survive these processes, but they can also survive processing temperatures up to about 400° C., preferably from about 25° C. to about 350° C., and more preferably from about 100° C. to about 300° C.

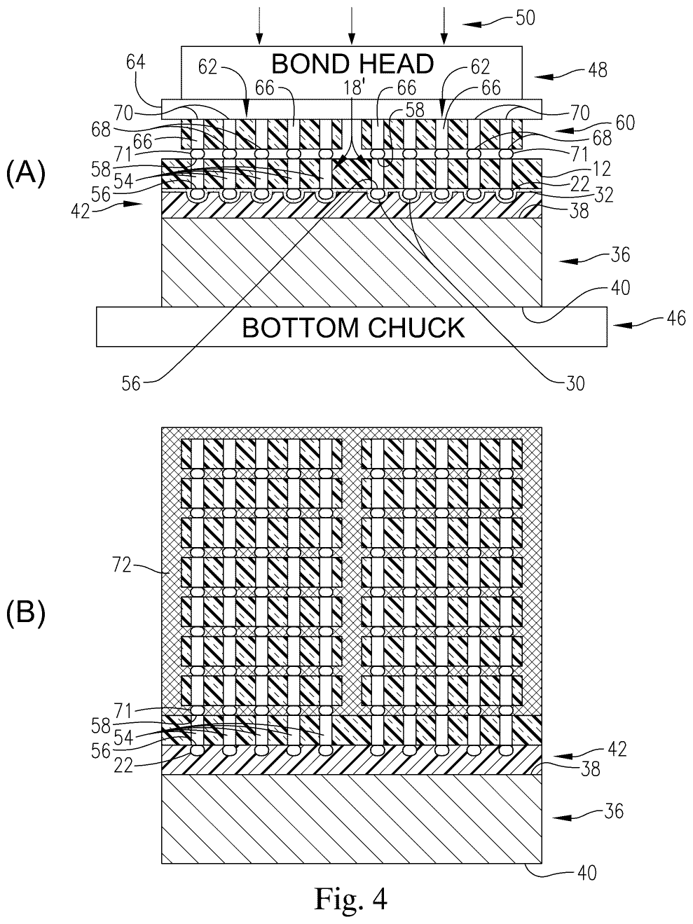

The above backside processing involved wafer-to-wafer bonding. In an alternative embodiment, the disclosed concept can be applied to chip-to-wafer bonding as well as chip stacking. Referring to FIG. 4, where like numbers represent like parts, the process described with respect to FIG. 1 can be repeated, but with the features 18 of first substrate 12 instead comprising through-silicon vias (“TSVs”) 54. TSVs 54 have first and second ends 56, 58 and are typically a metal, such as those described above with respect to pillars 20. Furthermore, solder bumps or balls 22 of first substrate 12 (i.e., “under” first bonding layer 32) are present and in contact with TSVs 54 at first end 56. In this embodiment, first substrate 12 has undergone backside thinning and is now acting as a landing wafer to which chips can be bonded.

Next, a chip structure 60 comprising one or more chips 62 (two such chips 62 are shown in FIG. 4(A)) supported on a carrier substrate 64 is introduced into the process. Chips 62 also include respective TSVs 66 with first and second ends 68, 70 and solder balls 71 at first end 68. Chip structure 60 is positioned such that its solder balls 71 that are attached to TSVs 66 of chip structure 60 align and contact the second ends 58 of TSVs 54, thus completing the connection. Bond head 48 applies heat and pressure to the chip structure 60 through carrier substrate 64 following the conditions described previously. Alternatively, the following parameters can be used: bonding head temperature less than about 150° C. or about 100° C.; bonding time about 1 second; bonding force about 10 N; and bottom chuck temperature about 80° C.

At this stage, molding material can be applied for protection according to conventional application methods, and the resulting structure can be processed as needed for the particular end use. Alternatively, instead of applying molding material at this stage, multiple such chip structures 60 (e.g., four, eight, twelve) can be stacked successfully as described above and before applying the molding material (see FIG. 4(B)). Additionally, each such chip structure could be the same, different, and/or chiplets. In this instance, a post-bond step can be applied after the last chip structure 60 has been attached. Post-bonding conditions are typically a bond head temperature of about 260° C. to about 400° C., a bond force of about 20 N to about 50 N, a bond time of less than about 10 seconds, and a bottom chuck temperature about 150° C. or greater.

Regardless of whether wafer-to-wafer bonding, chip-to-wafer bonding, or chip stacking was carried out, once processing is complete, the substrates 12 and 36 can be separated by any number of separation methods known to be appropriate for the particular bonding composition used to form second bonding layer 42 (e.g., laser debonding). Regardless of which means is utilized, a low mechanical force (e.g., finger pressure, gentle wedging) can then be applied to completely separate the substrates 12 and 36. After separation, any remaining first bonding layer 32 can be removed from the front surface 14 of first substrate 12 with a solvent capable of dissolving the particular material of which first bonding layer 32 is formed. Similarly, second bonding layer 42 may be removed from the first surface 38 of second substrate 36 with a solvent capable of dissolving the particular material of which second bonding layer 42 is formed, thus enabling reuse of second substrate 36. Examples of suitable cleaning solvents for nonpolar bonding materials include d-limonene, mesitylene, 1-dodecene, or mixtures thereof. Suitable solvents for cleaning polar bonding materials include γ-butyrolactone, cyclopentanone, benzyl alcohol, dimethyl sulfoxide, cyclohexanone, propylene glycol methyl ether, propylene glycol methyl ether acetate, N-methyl-2-pyrrolidone, 1,3-dioxolane, or mixtures thereof.

A number of advantages are achieved by the method and materials described herein. For example, the adhesive strength of the bond line 47 can be controlled and/or adjusted by the selection and/or loading of the bond line adhesion promoter in the first bonding layer 32. At the same time, the bond line adhesion promoter and adjustments to the bond line strength have negligible effects on other important performance characteristics of the dual-layer bonding materials.

A further advantage of the embodiment of FIG. 1 is that the first bonding layer 32 is typically a thermoplastic material, making it easier to remove than the curable thermoset material from which second bonding layer 42 is formed. Additionally, having a thermoplastic first bonding layer 32 allows for complete, or at least substantially complete, ablation when using laser debonding, thus alleviating the risk of damaging features on the device substrate (i.e., substrate 12) during and after debonding.

Another advantage is that the first bonding layer 32 decreases, or even completely prevents, the solder balls 22, copper pillars, and other devices or structures on the first substrate 12 and covered by first bonding layer 32 from deforming, shifting, experiencing a change in bump height, and/or experiencing other damage during the thermocompression bonding and subsequent backside processing of the first substrate 12, allowing for better 3DIC integration. This improvement can be observed visually (e.g., SEM) or acoustically (e.g., SAM) as well as through performance improvements, such as decreased device failure. Additionally, the method works with a wide range of pitches, including about 5 μm to about 160 μm, and preferably about 10 μm to about 30 μm.

It will also be appreciated that several variations can be made to the foregoing disclosure. For example, the first and second bonding layers can be “swapped.” That is, first bonding layer 32 can be formed on first surface 38 of second substrate 36 instead of on front surface 14 of first substrate 12, while second bonding layer 42 can be formed on the front surface 14 of first substrate 12 instead of on first surface 38 of second substrate 36. In either instance, the bonding compositions, layer formation processes, and bonding and debonding methods are the same as described above. An advantage of this variation is that having a thermoset material (i.e., the second bonding layer 42) adjacent the device substrate (first substrate 12) may provide better protection for features on first substrate 12 during processes carried out on the bonded substrates. Also, in the case of laser debonding, laser energy is passed through the carrier (second substrate 36) into the thermoplastic first bonding layer 32, which can be tuned to absorb the laser energy, thereby generating heat. Having features on the (device) first substrate 12 insulated and protected from this heating may be desirable in some cases. Thus, preferences will vary depending on the particular manufacturing processes and the concerns raised thereby.

An example of another variation is that in the above embodiments, the solder balls 22 are attached to a pillar or TSV, however, the solder ball can be attached via any conventional attachment point or mechanism, including metal posts, metal pads, and conducting layers. It will be appreciated that the various attachment mechanisms typically require the use of under-bump metal (“UBM”).

A further variation can take place during the formation of second bonding layer 42. In the illustrated embodiment, second bonding layer 42 was formed on the front surface 38 of second substrate 36. Alternatively, second bonding layer 42 can instead be formed on first bonding layer 32. In this embodiment, second substrate 36 is then bonded to formed second bonding layer 42 following the same bonding processes described above.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Solution for Forming 7-μm Thermoplastic Film for Topographical Wafers Having Solder Balls

In this example, 10.258 g of Matrimid® 5218 (Huntsman), 4.3965 g of OKP4HT (Osaka Gas Chemicals), 0.3451 g of BMI-2500 (Designer Molecules Inc.), 0.0154 g of Dicumyl peroxide (Sigma-Aldrich Inc.), and 84.985 g of Cyclopentanone (Neostar) were added in the order mentioned to a 250-ml amber glass bottle and mixed on a mixing wheel at about 20 rpm for 24 hours at room temperature until a homogeneous solution was obtained. The resulting solution was filtered through a 0.2-μm Meissner filter. The filtered solution had a solids percentage of 15%.

### Example 2

### Solution for Forming 2-μm Thermoplastic Film

In this example, 7.523 g of Matrimid® 5218 (Huntsman), 3.224 g of OKP4HT (Osaka Gas Chemicals), 0.253 g of BMI-2500 (Designer Molecules Inc.), 0.011 g of Dicumyl peroxide (Sigma-Aldrich Inc.), and 88.99 g of Cyclopentanone (Neostar) were added in the order mentioned to a 250-ml amber glass bottle and mixed on a mixing wheel at about 20 rpm for 24 hours at room temperature until a homogeneous solution was obtained. The resulting solution was filtered through a 0.2-μm Meissner filter. The filtered solution had a solids percentage of 11%.

### Example 3

### Solution for Forming Thermoplastic Laser Release Layer

In this example, 2.736 g of Matrimid® 5218 (Huntsman), 1.172 g of OKP4HT (Osaka Gas Chemicals), 0.092 of BMI-2500 (Designer Molecules Inc.), 0.004 g of Dicumyl peroxide (Sigma-Aldrich Inc.), and 96.0 g of Cyclopentanone (Neostar) were added in the order mentioned to a 250-ml amber glass bottle and mixed on a mixing wheel at about 20 rpm for 24 hours at room temperature until a homogeneous solution was obtained. The resulting solution was filtered through a 0.2-μm Meissner filter. The filtered solution had a solids percentage of 4%.

### Example 4

### Solution for Bonding to Epoxy Molding Compound Surface

In this example, 2.736 g of Matrimid® 5218 (Huntsman), 1.172 g of OKP4HT (Osaka Gas Chemicals), 0.092 of BMI-1700 (Designer Molecules Inc.), 0.004 g of Dicumyl peroxide (Sigma-Aldrich Inc.), and 96.0 g of Cyclopentanone (Neostar) were added in the order mentioned to a 250-ml amber glass bottle and mixed on a mixing wheel at about 20 rpm for 24 hours at room temperature until a homogeneous solution was obtained. The resulting solution was filtered through a 0.2-μm Meissner filter. The filtered solution had a solids percentage of 14%.

### Example 5

### Dual-Layer Temporary Bonding and Debonding

In this example, BrewerBOND® C1301-50 material, a curable adhesive thermoset material available commercially from Brewer Science, Inc. (Rolla, MO), and the solution prepared in Example 1 were used for temporary bonding and debonding of a carrier and a silicon device wafer. The thermoplastic material solution from Example 1 was coated on an eight-inch Si wafer to form a film about 7 μm thick. A carrier glass wafer was coated with 50 μm of BrewerBOND® C1301-50 material. The wafer pair was then bonded at 25° C., 1,000N for 3 minutes under vacuum (<5 mbar) in an EVG510 bonder (EV Group). The bonded materials were then subjected to thermal curing (300 mm hot plate, Cost Effective Equipment). The bonded pair was then subjected to thermal conditions simulating some additional processing steps. Additional details about the process conditions are listed in Table 1.

TABLE 1
Process Conditions

| | |
|---|---|
| BrewerBOND ® C1301-50 | Thermoplastic solution |
| | from Example 1 |
| Coat: 650 rpm, 500 rpm/s for 90 | Coat: 800 rpm, 500 rpm/s for 30 s |
| Bake: 60° C. for 1 minute, 120° C. | Bake: 60° C. for 1 minute, 120° C. |
| for 2 minutes | for 4 minutes |

Bond: 25° C., 1,000N for 3 minutes with vacuum <5 mbar on EVG510
Cure: 180° C. for 5 minutes, 220° C. for 10 minutes
Thermal simulation: 300° C. for 15 minutes on hotplate

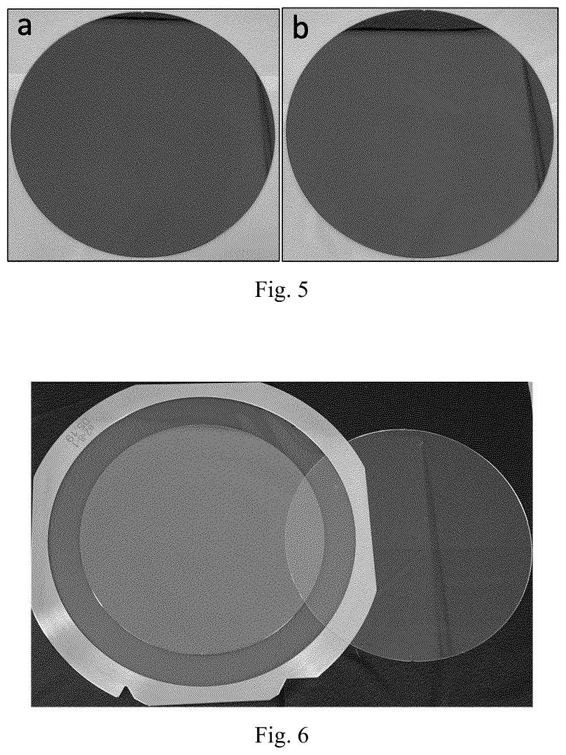

The bonded pair was inspected visually before and after the thermal simulation at 300° C. for 15 minutes on a hotplate. FIG. 5 shows that there are no obvious defects or voiding in the bond line after the thermal treatment.

Afterward, the wafer pair was successfully debonded by a SUSS DB12T mechanical debond tool, with the debonding process parameters being provided in Table 2.

TABLE 2
Process Parameters for SUSS DB12T Debond Tool

| | |
|---|---|
| Initiation force | 30N |
| Flex plate force | Ramped from 200N to 100N |
| Roller force | 500N |
| Roller speed | 2 mm/s |

The debonding occurred at the interface between BrewerBOND® C1301-50 material and thermoplastic material from Example 1. No material transfer was observed from either side. The photo images of debonded wafers are shown in FIG. 6.

### Example 6

### Bond Line Adhesion Between BrewerBOND® C1301 Material and Materials from Examples 1-4

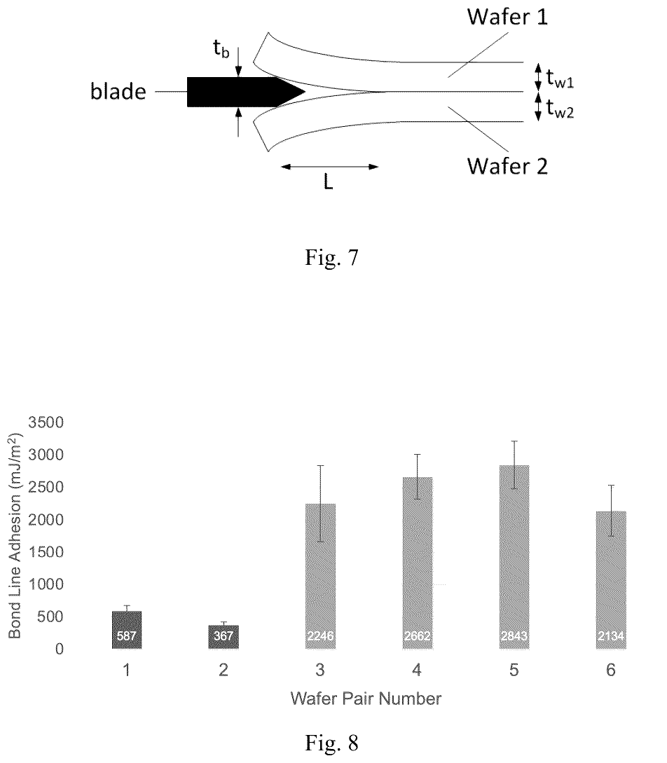

The bond line adhesion between the thermoplastic material from Examples 1-4 and BrewerBOND® C1301-50 curable adhesive thermoset material was evaluated by the Double Cantilever Beam Test (Maszara approach). Referring to FIG. 7, a razor blade having a known thickness is inserted into the bond line between the bonded wafer pairs. This leads to the separation of the two wafers at the bond line. The bond line adhesion (γ) is then calculated by the following equation:

$$γ = \frac{3 {t}_{b}^{2} {E}_{1} {t}_{w 1}^{3} {E}_{2} {t}_{w 2}^{3}}{16 {L}^{4} ( {E}_{1} {t}_{w 1}^{3} + {E}_{2} {t}_{w 2}^{3} )}$$

in which: E₁ and E₂ are the Young's Modulus for two types of wafers (in this Example, 1 for silicon and 2 for glass, both obtained from literature values); t_{w} is the thickness of the wafer (determined via chromatic distance measurements with dual sensors); t_{b} is the thickness of the razor blade; and L is the measured crack length.

In this Example, the thermoplastic materials from Examples 1-4 were coated on silicon wafers and bonded with BrewerBOND® C1301-50 curable adhesive thermoset material on glass wafers, or vice-versa in the case of wafer pair #6. Also, for wafer pairs #1 and #2, BrewerBOND® C1301-50 material was used in combination with BrewerBOND® T1101 and BrewerBOND® T1107 materials, respectively, two different commercially available thermoplastic temporary bonding materials (Brewer Science, Inc., Rolla MO), to provide a baseline for comparison. In total the bond line adhesion of 6 different wafter pairs was tested in this Example. The processes and materials used to prepare each of the six wafer pairs are listed in Table 3. The bond line adhesion for each wafer pair is shown in FIG. 8.

TABLE 3
Process Conditions for the Bond Line Adhesion Tests

| | | |
|---|---|---|
| Wafer Pair | Si wafer | Glass wafer |

Coat and Bake Process

| | | |
|---|---|---|
| 1 | BrewerBOND ® T1101 | BrewerBOND ® C1301-50 |
| | Coat: 650 rpm, 500 rpm/s | Coat: 650 rpm, 500 rpm/s |
| | for 90 s | for 90 s |
| | Bake: 60° C. for 1 minute, | Bake: 60° C. for 1 minute, |
| | 120° C., for 2 minutes | 120° C., for 2 minutes |
| 2 | BrewerBOND ® T1107 | BrewerBOND ® C1301-50 |
| | Coat: 650 rpm, 500 rpm/s | Coat: 650 rpm, 500 rpm/s |
| | for 90 s | for 90 s |
| | Bake: 60° C. for 1 minute, | Bake: 60° C. for 1 minute, |
| | 120° C., for 2 minutes | 120° C., for 2 minutes |

Bond and Cure Process

| | |
|---|---|
| 1, 2 | Bond: 25° C., 1,000N for 3 minutes with vacuum |
| | <5 mbar on EVG510 |
| | Cure: 180° C., for 5 minutes, 220° C., for 10 minutes |

Coat and Bake Process

| | | |
|---|---|---|
| 3 | Example 1 Material | BrewerBOND ® C1301-50 |
| | Coat: 800 rpm, 500 rpm/s | Coat: 650 rpm, 500 rpm/s |
| | for 30 s | for 90 s |
| | Bake: 60° C. for 1 minute, | Bake: 60° C. for 1 minute, |
| | 120° C. for 4 minutes | 120° C. for 2 minutes |
| 4 | Example 2 Material | BrewerBOND ® C1301-50 |
| | Coat: 800 rpm, 500 rpm/s | Coat: 800 rpm, 500 rpm/s |
| | for 30 s | for 90 s |
| | Bake: 60° C. for 1 minute, | Bake: 60° C. for 1 minute, |
| | 120° C. for 4 minutes | 120° C. for 2 minutes |
| 5 | Example 4 Material | BrewerBOND ® C1301-50 |
| | Coat: 1,000 rpm, | Coat: 650 rpm, |
| | 1,000 rpm/s for 90 s | 500 rpm/s for 90 s |
| | Bake: 60° C. for 1 minute, | Bake: 60° C. for 1 minutes, |
| | 120° C. for 4 minutes | 120° C. for 2 minutes |
| 6 | BrewerBOND ® C1301-50 | Example 3 Material |
| | Coat: 650 rpm, | Coat: 800 rpm, |
| | 500 rpm/s for 90 s | 500 rpm/s for 30 s |
| | Bake: 60° C. for 1 minute, | Bake: 60° C. for 1 minutes, |
| | 120° C. for 2 minutes | 120° C. for 4 minutes |

Bond and Cure Process

| | |
|---|---|
| 3-6 | Bond: 25° C., 1,000N for 3 minutes with vacuum <5 |
| | mbar on EVG510 |
| | Cure: 180° C., for 5 minutes, 220° C., for 10 minutes |

The materials in Examples 1-4 improved the bond line adhesion over the baseline by 3.6-7.7 times, as indicated by comparison of wafer pairs 1&2 (baseline) to wafer pairs 3-6 (Examples 1-4).

### Example 7

### Bond Line Adhesion Between BrewerBOND® C1301-50 Material and Materials Having Varying Amounts of Bond Line Adhesion Promoter

A series of thermoplastic materials made generally in accord with the Examples above using 2.3%, 3.5%, 5%, 7.5% and 10% BMI-2500 (Designer Molecules Inc.) as the bond line adhesion promoter were made and 15% solid content. The materials and the processing conditions were identical except for the bond line adhesion promoter content was varied as indicated in FIG. 9.

These results show the bond line adhesion can be further tuned by manipulating the percentage of the bond line adhesion promoter. For example, the bond line adhesion goes up from ˜2246 mJ/m² to ˜7678 mJ/m² as the promoter in the polymer increased from 2.3% to 10.0%, 12 times higher than the BrewerBOND® T1101 material, which has no bond line adhesion promoter. The change of the promoter percentage has limited effect on the k value of the coated material, so that the material is suitable as a thermoplastic layer in laser debonding processes.

### Example 8

### Solder Bump Coverage and Protection

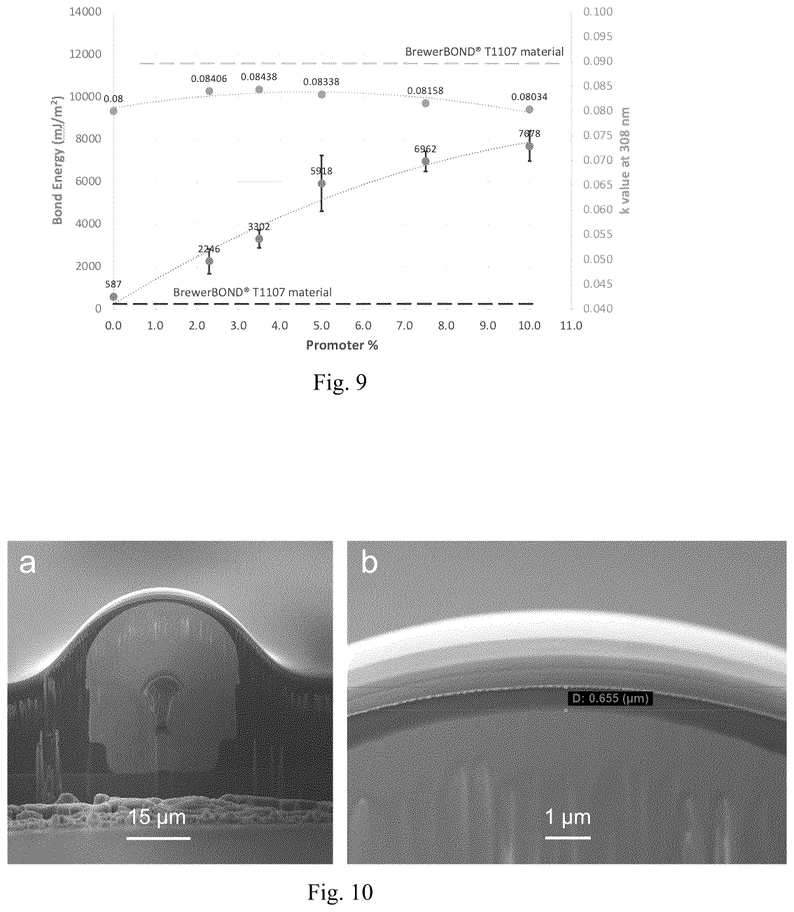

The material from Example 1 was coated on a topographical wafer coupon (2 in.×2 in.) having a solder bump grid array using the same conditions shown for the Example 1 material in Table 3 above. The height of the bumps on the wafer was about 32-36 μm. The SEM images of FIG. 10 show that the resulting coating provided full coverage on the bumps. The film thickness on bump top was about 655 nm. Additionally, areas having different densities were fully covered by the coating.

Afterward, the coated coupon was bonded with BrewerBOND® C1301-50 material on a 4-inch glass carrier wafer. The process parameters were the same as for the Example 1 material in Table 3. The bonded wafer pair was tested in a simulated thermocompression bonding (TCB) process. In the simulation, the wafer pair was compressed by an Apogee bonder (Cost Effective Equipment) using 1,300 N at 300° C. for 15 s. After the TCB process, the wafer pair was mechanically debonded, and the coating formed by the material of Example 1 was removed by soaking it in 1,3-dioxolane. The solder balls on the top parts of the bumps retained their structure and shape, thus showing the survivability of bumps under the protection of the coating.

### Example 9

### Laser Debonding

The materials from Examples 1-4 are compatible with laser debonding. In this Example, the materials from Examples 1 and 4 were coated on 300-mm silicon wafers and then bonded with BrewerBOND® C1301-50 material on glass carrier wafers using the same conditions listed in Table 3 for Example 1. The laser beam penetrated the BrewerBOND® C1301-50 material due to its transparency to the laser wavelength and ablated the underlying thermoplastic layer to achieve debonding. The wavelength of the laser beam was 308 nm, and the energy was 240 mJ/cm². There were 5% overlapping in the laser shots to ensure all the coated areas were ablated. Afterwards, the thermoplastic materials were removed (cleaned) easily using 1,3-dioloxlane.

### Example 10

### Temporary Bonding of EMC Wafers

An epoxy mold compound (EMC) wafer was obtained from Industrial Technology Research Institute (ITRI), Taiwan. The EMC wafer had a diameter of 288 mm, a thickness between 300 to 400 μm, and silica as filler. The coefficient of thermal expansion (CTE) of the wafer was about 7.0 ppm. The material from Example 4 was coated on the EMC wafer and bonded with BrewerBOND® C1301-50 material on a glass carrier wafer (Gorilla glass) using the process conditions listed in Table 3 for Example 4. The wafer pair was then subjected to 250° C. heat treatment for 15 minutes.

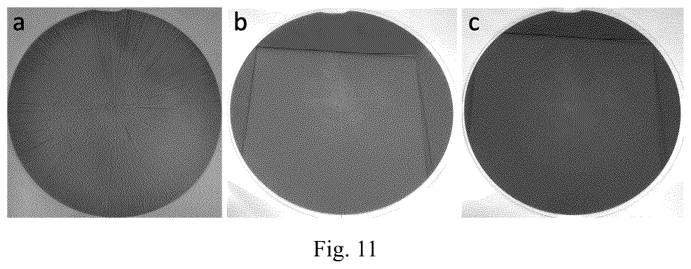

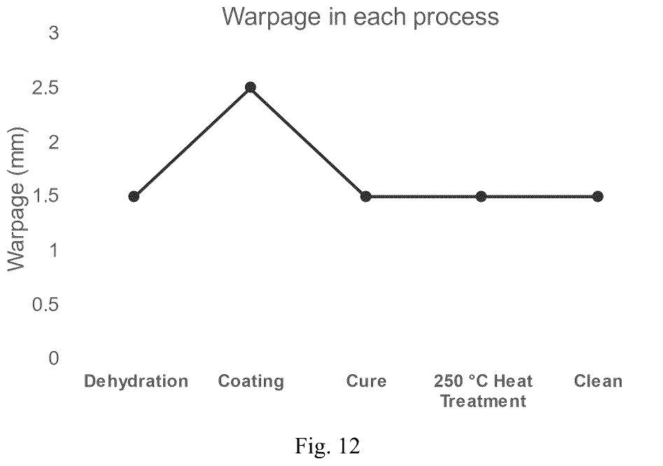

Images of the wafer pair at various stages are shown in FIG. 11. FIG. 11a shows the EMC wafer coated with the thermoplastic material, and FIG. 11b shows the appearance of the wafer pair after bonding. FIG. 11c shows that the wafer pair survived the heat treatment at 250° C. for 15 minutes. The warpage was measured at each stage in the process and is provided in FIG. 12. Warpage is measured by placing the wafer on a horizontal and flat surface and measuring the distance between the highest wafer edge and the flat surface using a ruler. The Example 4 material showed good performance in the temporary bonding of EMC wafers.

As shown in FIG. 12, the warpage can be controlled to about 1.5 mm in most stages of the process. This is due to the strong bond line adhesion as well as the use of Gorilla glass, which has similar CTE with the EMC wafer. The warpage was highest during coating, but even then, the warpage still did not exceed about 2.5 mm.

### Example 11A

### Preparation of Bond Line Adhesion Promoter a with Endcap

### Molar Ratio 1:0.85 of Diepoxide:Diol-Containing Monomer

A polyhydroxyether was prepared between bisphenol A diglycidyl ether (DER™ 332, available from Sigma-Aldrich) and 4,4-dihydroxybenzophenone with eugenol as an endcap. The molar ratio was 1:0.85, with diepoxide in excess of the diol-containing monomer.

First, 51.182 g of bisphenol A diglycidyl ether and 43.162 g of cyclohexanone were mixed together. A condenser and glass stir shaft with paddle were added, and mechanical stirring was carried out at 80 rpm under a nitrogen atmosphere. Next, 27.316 g 4,4-dihydroxybenzophenone were added to a reactor, and the bisphenol A diglycidyl ether-cyclohexanone mixture was added to the reaction.

Eugenol (7.3915 g) was added to the reaction, followed by heating of the solution to 150° C. Ethyltriphenyl phosphonium (catalyst; 1.782 g) was added to the reaction, and heating at 150° C. was continued for about 24 hours. The heat was turned off, and the reaction was allowed to cool to about 130° C., after which the solution was diluted with 77.973 g of cyclopentanone to achieve a solids content of about 41.28% by weight. The MW of the solution was checked by GPC (MW THE method) after the reaction was finished. The MW was 19,689 Daltons, the Mn was 6519 Daltons, and the polydispersity was 3.02.

### Bond Line Adhesion Promoter A

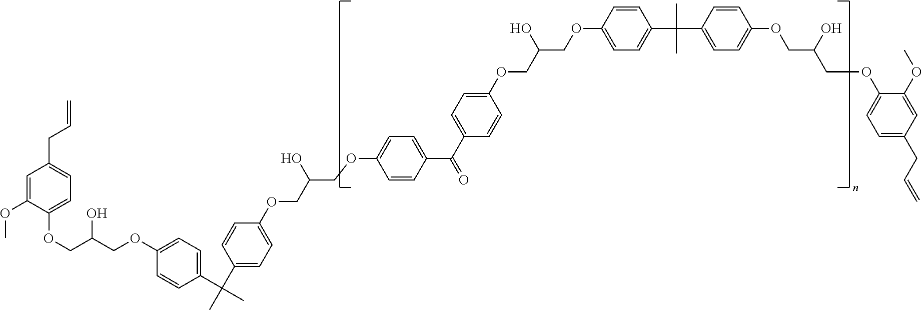

### Example 11B

### Preparation of Bond Line Adhesion Promoter a with Endcap

### Molar Ratio 1:0.75 of Diepoxide:Diol-Containing Monomer

A polyhydroxyether was prepared between bisphenol A diglycidyl ether (DER™ 332) and 4,4-dihydroxybenzophenone with eugenol as an endcap. The molar ratio was 1:0.75, with diepoxide in excess of the diol-containing monomer.

First, 51.089 g of bisphenol A diglycidyl ether and 41.415 g of cyclohexanone were mixed together. A condenser and glass stir shaft with paddle were added, and mechanical stirring was carried out at 80 rpm under a nitrogen atmosphere. Next, 24.099 g 4,4-dihydroxybenzophenone were added to a reactor.

Eugenol (12.325 g) was added to the reaction, followed by heating of the solution to 150° C. Ethyltriphenyl phosphonium (catalyst; 1.785 g) was added to the reaction, and heating at 150° C. was continued for about 24 hours. The heat was turned off, and the reaction was allowed to cool to about 130° C., after which the solution was diluted with 73.995 g of cyclopentanone to achieve a solids content of about 42.74% by weight. The MW of the solution was checked by GPC (MW THE method) after the reaction was finished. The MW was 9,457 Daltons, the Mn was 3,847 Daltons, and the polydispersity was 2.46.

### Example 11C

### Preparation of Bond Line Adhesion Promoter a with Endcap

### Molar Ratio 1:0.60 of Diepoxide:Diol-Containing Monomer

A polyhydroxyether was prepared between bisphenol A diglycidyl ether (DER™ 332) and 4,4-dihydroxybenzophenone with eugenol as an endcap. The molar ratio was 1:0.60, with diepoxide in excess of the diol-containing monomer.

First, 51.16 g of bisphenol A diglycidyl ether and 38.851 g of cyclohexanone were mixed together. A condenser and glass stir shaft with paddle were added, and mechanical stirring was carried out at 80 rpm under a nitrogen atmosphere. Next, 19.295 g 4,4-dihydroxybenzophenone were added to a reactor.

Eugenol (19.717 g) was added to the reaction, followed by heating of the solution to 150° C. Ethyltriphenyl phosphonium (catalyst; 1.795 g) was added to the reaction, and heating at 150° C. was continued for about 24 hours. The heat was turned off, and the reaction was allowed to cool to about 130° C., after which the solution was diluted with 69.359 g of cyclopentanone to achieve a solids content of about 45% by weight. The MW of the solution was checked by GPC (MW THE method) after the reaction was finished. The MW was 6,094 Daltons, the Mn was 2,724 Daltons, and the polydispersity was 2.24.

### Example 12A

### Formulation Using Bond Line Adhesion Promoter A

Bond Line Adhesion Promoter A from Example 11A was blended with BrewerBOND® T1107 material, a commercially available thermoplastic bonding material from Brewer Science, Inc. (Rolla, MO), at about 0.1%, about 1%, about 5%, and about 15% based on the weight of the BrewerBOND® T1107 material. The precise amounts are indicated in Tables 4-7 below:

TABLE 4
Weights used, final percentages, and polymer ratios
used in 0.1% adhesion promoter solution

| | Weight | Solution |
|---|---|---|
| Material | (g) | Percentages |
| BrewerBOND ® T1107 | 10 | 99.82% |
| Example 13A Adhesion Promotor | 0.018 | 0.18% |
| Solution | | |

TABLE 5
Weights used, final percentages, and polymer
ratios used in 1% adhesion promoter solution

| | Weight | Solution |
|---|---|---|
| Material | (g) | Percentages |
| BrewerBOND ® T1107 | 9.914 | 98.76% |
| Example 13A Adhesion Promotor | 0.1242 | 1.24% |
| Solution | | |

TABLE 6
Weights used, final percentages, and polymer
ratios used in 5% adhesion promoter solution

| | Weight | Solution |
|---|---|---|
| Material | (g) | Percentages |
| BrewerBOND ® T1107 | 9.513 | 94.88% |
| Example 13A Adhesion Promotor | 0.513 | 5.12% |
| Solution | | |

TABLE 7
Weights used, final percentages, and polymer
ratios used in 15% adhesion promoter solution

| | Weight | Solution |
|---|---|---|
| Material | (g) | Percentages |
| BrewerBOND ® T1107 | 8.507 | 84.98% |
| Example 13A Adhesion Promotor | 1.503 | 15.02% |
| Solution | | |

After mixing all the solutions were fully transparent and no visible phase separation was observed.

### Example 12B

### Bonding Using Bond Line Adhesion Promoter A

The solutions from Example 12A were coated on 100 mm reclaimed silicon wafers with a spin speed of 1,250 rpm, an acceleration of 500 rpm/s, and a time of 45 s. The coated solutions were subjected to a soft bake after spinning at 60° C. for 1 min and 220° C. for 4 mins. The coated wafers were set aside while BrewerBOND® C1301-50 material was coated on a 4″ glass Eagle XG wafer with a spin speed of 650 rpm, an acceleration of 500 rpm/s, and time of 90 s. Once the wafers were coated with the BrewerBOND® C1301-50 material, they were each bonded to one of the previously coated reclaimed wafers to form a wafer pair using an EVG510 Thermocompression Bond Chamber with the following bond process: temperature 25° C., force 1,000 N, and bond time of 3 mins.

After each wafer pair was bonded, the BrewerBOND® C1301-50 material side of the pair was placed on a hotplate at 180° C. for 5 mins and then at 220° C. for 5 mins to react the contact surface of BrewerBOND® C1301-50 material with the bond line adhesion promoter that had been added to the BrewerBOND® T1107 material as well as to crosslink the BrewerBOND® C1301-50 material. Once the wafer pair cooled to room temperature, adhesion was tested via the Maszara Razor Blade Test. The crack lengths and calculated bond energies are shown for the varied solutions in Table 8.

TABLE 8
Crack Lengths and Bond Energies

| Additive Percentage | Measured Crack Length(cm) | Bond Energy (J/m²) |
|---|---|---|
| 0.1% | 2.6 | 0.54 |
| 1% | 2.7 | 0.47 |
| 5% | 2.8 | 0.4 |
| 15% | 2 | 1.55 |

The solution with 15% bond line adhesion promoter loading showed a significant increase in bond energy at the material interface as compared to the 0.1% formulation.

### Example 13A

### Preparation of Bond Line Adhesion Promoter B (No Endcap)

In this Example, a bond line adhesion promoter was prepared with a ratio between two diols (diallylbisphenol A and dihydroxybenzophenone) being 25% diallylbisphenol A (x=1) to 75% dihydroxybenzophenone (y=3) and a stoichiometric ratio between the diepoxy and diol being 0.7 with the diepoxy being in excess to the diol. 51.062 g of bisphenol A diglycidyl ether, 8.095 g of 2,2′-diallylbisphenol A, and 32.811 g of GBL were mixed together in a reactor. The reactor was equipped with a condenser and glass stir shaft with stir paddle set to 80 rpm. The reactor was also provided with a protective nitrogen atmosphere. Then, 16.869 g of 4,4-dihydroxybenzophenone was added to the reactor along with 1.787 g ethyltriphenyl phosphonium bromide. The reaction was allowed to proceed at 150° C. for 8 hours to obtain Bond Line Adhesion Promoter B (structure shown below). As the reaction cooled (to ˜ 130° C.) it was diluted with cyclopentanone to ˜46% solids. The result was a clear yellow solution with warm honey-like viscosity. The weight average molecular weight was determined by gel permeation chromatography (GPC) to be 10,576 Daltons, the Mn was 2,879 Daltons, and the polydispersity was 3.67.

### Bond Line Adhesion Promoter B

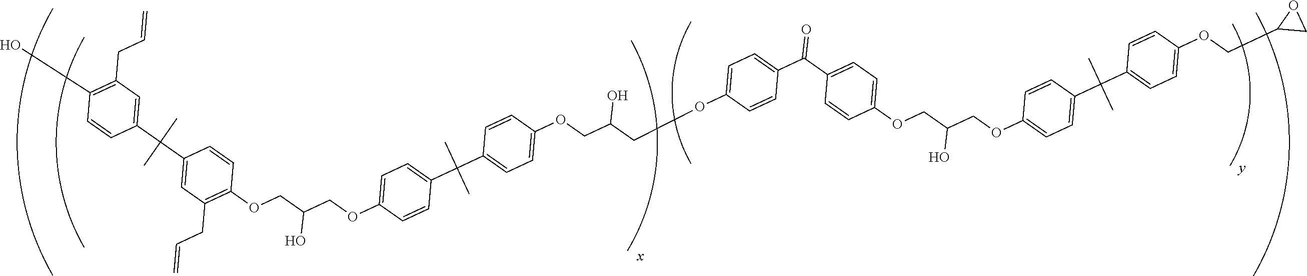

### Example 13B

### Preparation of Bond Line Adhesion Promoter B (No Endcap)

In this Example, a bond line adhesion promoter was prepared with a ratio between two diols (diallylbisphenol A and dihydroxybenzophenone) being 50% diallylbisphenol A (x=2) to 50% dihydroxybenzophenone (y=2) and a stoichiometric ratio between the diepoxy and diol being 0.98 with the diepoxy being in excess to the diol. 51.16 g of bisphenol A diglycidyl ether, 22.75 g of 2,2′-diallylbisphenol A, and 40.72 g of GBL were mixed together in a reactor. The reactor was equipped with a condenser and glass stir shaft with stir paddle set to 80 rpm. The reactor was also provided with a protective nitrogen atmosphere. Then, 15.76 g of 4,4-dihydroxybenzophenone was added to the reactor along with 1.790 g ethyltriphenyl phosphonium bromide. The reaction was allowed to proceed at 150° C. for about 24 hours to obtain Bond Line Adhesion Promoter B (structure shown in Example 13A). As the reaction cooled (to ˜ 130° C.) it was diluted with 72.61 g cyclopentanone to ˜43.75% solids. The result was a clear yellow solution with warm honey-like viscosity. The weight average molecular weight was determined by gel permeation chromatography (GPC) to be 58, 131 Daltons, the Mn was 9,567 Daltons, and the polydispersity was 6.08.

### Example 13C

### Preparation of Bond Line Adhesion Promoter B (No Endcap)

In this Example, a bond line adhesion promoter was prepared with a ratio between two diols (diallylbisphenol A and dihydroxybenzophenone) being 25% diallylbisphenol A (x=1) to 75% dihydroxybenzophenone (y=3) and a stoichiometric ratio between the diepoxy and diol being 0.7 with the diepoxy being in excess to the diol. 51.063 g of bisphenol A diglycidyl ether, 8.081 g of 2,2′-diallylbisphenol A, and 32.168 g of GBL were mixed together in a reactor. The reactor was equipped with a condenser and glass stir shaft with stir paddle set to 80 rpm. The reactor was also provided with a protective nitrogen atmosphere. Then, 16.875 g of 4,4-dihydroxybenzophenone was added to the reactor along with 1.783 g ethyltriphenyl phosphonium bromide. The reaction was allowed to proceed at 150° C. for about 24 hours to obtain Bond Line Adhesion Promoter B (structure shown in Example 13A). As the reaction cooled (to ˜ 130° C.) it was diluted with cyclopentanone to ˜44.9% solids. The result was a clear yellow solution with warm honey-like viscosity. The weight average molecular weight was determined by gel permeation chromatography (GPC) to be 31,736 Daltons, the Mn was 6,825 Daltons, and the polydispersity was 4.65.

### Example 14

### Formulation Using Bond Line Adhesion Promoter B

Bond Line Adhesion Promoter B from Example 13A was blended with BrewerBOND® T1107 material, a commercially available thermoplastic bonding material from Brewer Science, Inc. (Rolla, MO), at about 1%, about 5%, and about 10% based on the weight of the BrewerBOND® T1107 material. The precise amounts are indicated in Tables 9-11 below:

TABLE 9
Weights used, final percentages, and polymer
ratios used in 1% adhesion promoter solution

| | Weight | Solution | Polymer |
|---|---|---|---|
| Material | (g) | Percentages | Ratios |
| BrewerBOND ® T1107 | 10.025 | 98.84% | 95.68% |
| Example 13A Adhesion Promotor | 0.118 | 1.16% | 4.32% |
| Solution | | | |

TABLE 10
Weights used, final percentages, and polymer
ratios used in 5% adhesion promoter solution

| | Weight | Solution | Polymer |
|---|---|---|---|
| Material | (g) | Percentages | Ratios |
| BrewerBOND ® T1107 | 9.987 | 94.99% | 83.18% |
| Example 13A Adhesion Promotor | 0.527 | 5.01% | 16.82% |
| Solution | | | |

TABLE 11
Weights used, final percentages, and polymer
ratios used in 10% adhesion promoter solution

| | Weight | Solution | Polymer |
|---|---|---|---|
| Material | (g) | Percentages | Ratios |
| BrewerBOND ® T1107 | 10.005 | 90.72% | 71.82% |
| Example 13A Adhesion Promotor | 1.024 | 9.28% | 28.18% |
| Solution | | | |

After mixing all the solutions were fully transparent and no visible phase separation was observed.

### Example 15

### Bonding Using Bond Line Adhesion Promoter B

The solutions from Example 14 were coated on 100 mm reclaimed silicon wafers with a spin speed of 1,250 rpm, an acceleration of 500 rpm/s, and a time of 45 s. The coated solutions were subjected to a soft bake after spinning at 60° C. for 1 min and 220° C. for 4 mins. The coated wafers were set aside while BrewerBOND® C1301-50 material was coated on a 4″ glass Eagle XG wafer with a spin speed of 650 rpm, an acceleration of 500 rpm/s, and time of 90 s. Once the wafers were coated with the BrewerBOND® C1301-50 material, they were each bonded to one of the previously coated reclaimed wafers to form a wafer pair using an EVG510 Thermocompression Bond Chamber with the following bond process: temperature 25° C., force 1000 N, and bond time of 3 mins. After each wafer pair was bonded, the BrewerBOND® C1301-50 material side of the pair was placed on a hotplate at 180° C. for 5 mins and then at 220° C. for 5 mins to react the contact surface of BrewerBOND® C1301-50 material with the bond line adhesion promoter that had been added to the BrewerBOND® T1107 material as well as to crosslink the BrewerBOND® C1301-50 material. Once the wafer pair cooled to room temperature, adhesion was tested via the Maszara Razor Blade Test. The crack lengths and calculated bond energies are shown for the varied solutions in Table 12.

TABLE 12
Crack Lengths and Bond Energies

| Additive Percentage | Measured Crack Length(cm) | Bond Energy (J/m²) |
|---|---|---|
| 1% | 2.9 | 0.35 |
| 5% | 2.1 | 1.27 |
| 10% | 1.3 | 8.66 |

The solution from 10% bond line adhesion promoter loading showed a sufficiently high bond energy at the material interface that the BrewerBOND® C1301-50 material transferred over to the other material surface.

### Example 16

### Performance of Examples 12A and 14 Formulations

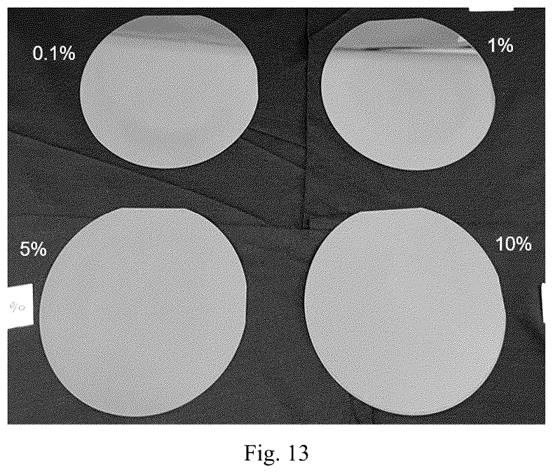

The performance properties of the Examples 12A (Bond Line Adhesion Promoter A) and 14 (Bond Line Adhesion Promoter B) formulations were tested for crack length and bond energy following the previously described procedures. These results are reported in Tables 13-17. FIG. 13 shows photographs of 25% allyl-containing Bond Line Adhesion Promoter B in the Table 9 formulations where Bond Line Adhesion Promoter B was included at 0.1% (top left), 1% (top right), 5% (bottom left), and 10% (bottom right) by weight, based on the total weight of the formulation taken as 100% by weight.

TABLE 13
Molecular Weight (MW) Comparisons
(Bond Line Adhesion Promoter A)

| | Bond Line | | | |
|---|---|---|---|---|
| Bond Line | Adhesion | Crack | Bond | |
| Adhesion | Promoter | Length | Energy | |
| Promoter | Percentage^{A} | (cm) | (J/m²) | MW |
| A | 0.1% | 2.6 | 0.54 | 6,094 |
| A | 1% | 2.9 | 0.35 | 6,094 |
| A | 5% | 3 | 0.31 | 6,094 |
| A | 15% | 1.4 | 6.44 | 6,094 |
| A | 0.1% | 2.9 | 0.35 | 9,457 |
| A | 1% | 2.7 | 0.47 | 9,457 |
| A | 5% | 2.5 | 0.63 | 9,457 |
| A | 15% | 1.5 | 4.89 | 9,457 |
| A | 0.1% | 2.6 | 0.54 | 19,689 |
| A | 1% | 2.7 | 0.47 | 19,689 |
| A | 5% | 2.8 | 0.40 | 19,689 |
| A | 15% | 2.0 | 1.55 | 19,689 |

^{A}By weight, based on total weight of the composition taken as 100% by weight.

TABLE 14
Endcapped vs. Non-endcapped Comparison
(Bond Line Adhesion Promoter A).

| | Bond Line | | | | |
|---|---|---|---|---|---|
| Bond Line | Adhesion | | Crack | Bond | |
| Adhesion | Promoter | Endcapped/ | Length | Energy | |
| Promoter | Percentage^{A} | No Endcap | (cm) | (J/m²) | MW |
| A | 0.1% | Endcapped | 2.6 | 0.54 | 6,094 |
| A | 1% | Endcapped | 2.9 | 0.35 | 6,094 |
| A | 5% | Endcapped | 3 | 0.31 | 6,094 |
| A | 15% | Endcapped | 1.4 | 6.44 | 6,094 |
| A | 0.1% | None | 3.1 | 0.27 | 5,416 |
| A | 1% | None | 3.1 | 0.27 | 5,416 |
| A | 5% | None | 3.4 | 0.19 | 5,416 |
| A | 15% | None | 3 | 0.31 | 5,416 |

^{A}By weight. based on total weight of the composition taken as 100% by weight.

TABLE 15
Endcapped and Non-endcapped Bond Line Adhesion Promoter
A Compared to Main Chain Bond Line Adhesion Promoter B.

| | Bond Line | | | | |
|---|---|---|---|---|---|
| Bond Line | Adhesion | Endcapped/ | Crack | Bond | |
| Adhesion | Promoter | Main Chain/ | Length | Energy | |
| Promoter | Percentage^{A} | No Endcap | (cm) | (J/m²) | MW |
| A | 0.1% | Endcapped | 2.6 | 0.54 | 6,094 |
| A | 1% | Endcapped | 2.9 | 0.35 | 6,094 |
| A | 5% | Endcapped | 3 | 0.31 | 6,094 |
| A | 15% | Endcapped | 1.4 | 6.44 | 6,094 |
| B | 0.1% | Main Chain | 1.6 | 3.78 | 49,092 |
| B | 1% | Main Chain | 1.5 | 4.89 | 49,092 |
| B | 5% | Main Chain | 1.3 | 8.66 | 49,092 |
| B | 15% | Main Chain | 1.4 | 6.44 | 49,092 |
| A | 0.1% | None | 3.1 | 0.27 | 5,416 |
| A | 1% | None | 3.1 | 0.27 | 5,416 |
| A | 5% | None | 3.4 | 0.19 | 5,416 |
| A | 15% | None | 3 | 0.31 | 5,416 |

^{A}By weight, based on total weight of the composition taken as 100% by weight.

TABLE 16
Bond Line Adhesion Promoter B Diallyl Percentage Loading

| | | Bond Line | | | |
|---|---|---|---|---|---|
| Bond Line | | Adhesion | Crack | | |
| Adhesion | Diallyl | Promoter | Length | Bond | |
| Promoter | Percentage^{A} | Percentage^{B} | (cm) | Energy(J/m²) | MW |
| B | 25% | 0.1% | 2.5 | 0.63 | 30,242 |
| B | 25% | 1% | 2.5 | 0.63 | |
| B | 25% | 5% | 1.2 | 11.93 | |
| B | 25% | 10% | 1.2 | 11.93 | |
| B | 100% | 0.1% | 1.6 | 3.78 | 49,092 |
| B | 100% | 1% | 1.5 | 4.89 | |
| B | 100% | 5% | 1.3 | 8.66 | |
| B | 100% | 15% | 1.4 | 6.44 | |
| B | 50% | 0.1% | 1.9 | 1.93 | 58,131 |
| B | 50% | 1% | 1.4 | 6.54 | |
| B | 50% | 5% | 1.1 | 17.15 | |
| B | 50% | 15% | 0.9 | 38.27 | |

^{A}Refers to the molar % of the diallyl-containing monomer in the bond line adhesion promoter.
^{B}By weight, based on total weight of the composition taken as 100% by weight.

TABLE 17
Comparison of Polymer MW and Allyl Percentage

| | | Molar Ratio | | | |
|---|---|---|---|---|---|
| | Bond Line | Diepoxide | | | |
| | Adhesion | Monomer to | Crack | Bond | |
| Diallyl | Promoter | Diallyl | Length | Energy | |
| Percentage^{A} | Percentage^{B} | Monomer | (cm) | (J/m²) | MW |
| 25% | 0.1% | 1:0.96 | 2.5 | 0.63 | 30,242 |
| 25% | 1% | | 2.5 | 0.63 | |
| 25% | 5% | | 1.2 | 11.93^{C} | |
| 25% | 10% | | 1.2 | 11.93^{C} | |
| 100% | 0.1% | 1:0.96 | 1.6 | 3.78 | 49,092 |
| f100% | 1% | | 1.5 | 4.89 | |
| 100% | 5% | | 1.3 | 8.66^{C} | |
| 100% | 15% | | 1.4 | 6.44^{C} | |
| 25% | 0.1% | 1:0.70 | | | 10,576 |
| 25% | 1% | | 2.9 | 0.35 | |
| 25% | 5% | | 2.1 | 1.27 | |
| 25% | 10% | | 1.3 | 8.66^{C} | |

^{A}Refers to the molar % of the diallyl-containing monomer in the bond line adhesion promoter
^{B}By weight, based on total weight of the composition taken as 100% by weight.
^{C}BrewerBOND ® C1301-50 material had partial transfer to the film.

### Example 16

### Preparation of Bond Line Adhesion Promoter C

In this procedure, 2-butyl-2-ethyl-1,3-bis(cyanoacetoxy) propane (“BEBCAP”; biscyanoacetate monomer) and 1,3-bis(4-formylphenoxy)-2-hydroxypropane (“4EPIDA”; dialdehyde monomer) were copolymerized at room temperature in 70/30 ratio of methyl 3-methoxypropionate (MMP)/gamma-butyrolactone (GBL) solvent in the presence of 5 mol % triethylamine based on the moles of dialdehyde and at a calculated polymer solids content of 30 wt. %. The reaction was allowed to proceed for 48 hours, after which the catalyst was neutralized by the addition of a stoichiometric amount of trifluoroacetic acid. In a 2 L resin kettle fitted with an overhead stir motor were combined 94.843 grams (53.7 mmol) of BEBCAP, 99.770 grams (53.7 mmol) of 4EPIDA, 16.300 grams (3.2 mmol) of 10% triethylamine (Sigma-Aldrich, St. Louis MO) in propylene glycol methyl ether, and 393.71 grams of a 70/30 MMP/GBL (Sigma-Aldrich, St. Louis MO). The contents were stirred for 48 hours at room temperature, over which time the solution steadily grew more viscous, forming a thick, transparent yellow-brown solution. The solution was then neutralized by adding 12.05 grams of acidic ion exchange beads. Gel permeation chromatography (GPC) analysis of the molecular weight characteristics of the resulting polymer yielded a weight-average molecular weight (Mw) of 116927, number-average molecular weight (Mn) of 11939, and PDI of 9.79

### Bond Line Adhesion Promoter C

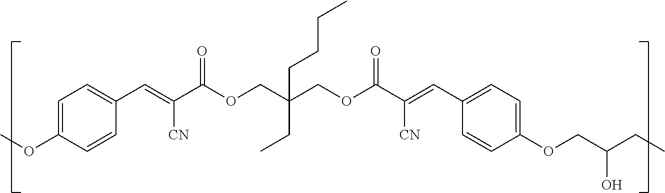

### Example 17

### Addition of Bond Line Adhesion Promoter C to BrewerBOND® T1107 Material

In this example, 13.061 g of BrewerBOND® T1107 material, and 0.65 g Bond Line Adhesion Promoter C from Example 16 were added in the order mentioned to a 20 mL vial and mixed on a mixing wheel at about 20 rpm for 24 hours at room temperature until a homogeneous solution was obtained. The solution had a solids percentage of 12.87%.

### Example 18

### Testing Solution from Example 17 for Bond Line Adhesion to BrewerBOND® C1301-50 Material

Solution from Example 17 was spin coated at 2 μm film thickness on 200 mm Si wafer and BrewerBOND® C1301-50 material was coated at 50 μm on 200 mm eagle XG glass followed by bonding of the two wafers to test the bond line increase. Table 18 provides the process conditions.

TABLE 18
Process Conditions

| | |
|---|---|
| Si wafer | Glass wafer |

Coat and Bake Process

| | |
|---|---|
| Solution 17 | BrewerBOND ® C1301-50 |
| Coat: 1250 rpm, 500 rpm/s for 90 s | Coat: 650 rpm, 500 rpm/s for 90 s |
| Bake: 60° C. for 1 minute, 220° C. | Bake: 120° C. for 4 minutes |
| for 4 minutes | |

Bond and Cure Process
Bond: 25° C., 1,000N for 3 minutes with vacuum <5 mbar on EVG510
Cure: 180° C. for 5 minutes, 220° C. for 5 minutes

After bonding the wafers were then tested for adhesion using the razor blade insertion test. Solution 17 had a crack length of 2.3 cm with BrewerBOND® C1301-50, which calculates to a bond energy of 1.37 J/m².

1. A bonding method comprising separating bonded first and second substrates, wherein:
said first substrate comprises a front surface, there being a first bonding layer on said front surface;
said second substrate comprises a first surface, there being a second bonding layer on said first surface, said second bonding layer being in contact with said first bonding layer; and
at least one of said first and second bonding layers comprising a bond line adhesion promoter that is covalently bonded with a component present in the other of said first and second bonding layers.

2. The method of claim 1, wherein said bond line adhesion promoter comprises a functional group that is covalently bonded with said component, said functional group being chosen from imides, vinyls, allyls, hydroxys, epoxides, silicon hydrides, esters, alkynes, amines, ketone, aldehydes, amides, thiols, or mixtures thereof.

3. The method of claim 1, wherein:
said bond line adhesion promoter comprises a quantity of a functional group covalently bonded with said component; and
said first bonding layer comprises one or both of a polymer or oligomer that is different from said bond line adhesion promoter, wherein said one or both of said polymer or oligomer comprises less than about 10% of said quantity of said functional group covalently bonded with said component.

4. The method of claim 2, wherein said bond line adhesion promoter comprises recurring monomeric units and about 50% or more of said recurring monomeric units comprises at least one of said functional groups bonded with said component.

5. The method of claim 1, wherein said first bonding layer comprises one or both of a polymer or oligomer that is different from said bond line adhesion promoter, wherein the total quantity of said one or both of said polymer or oligomer is about 30% to about 99.8% by weight, based on the weight of the first bonding layer taken as 100% by weight.

6. The method of claim 1, where said bond line adhesion promoter comprises a structure chosen from 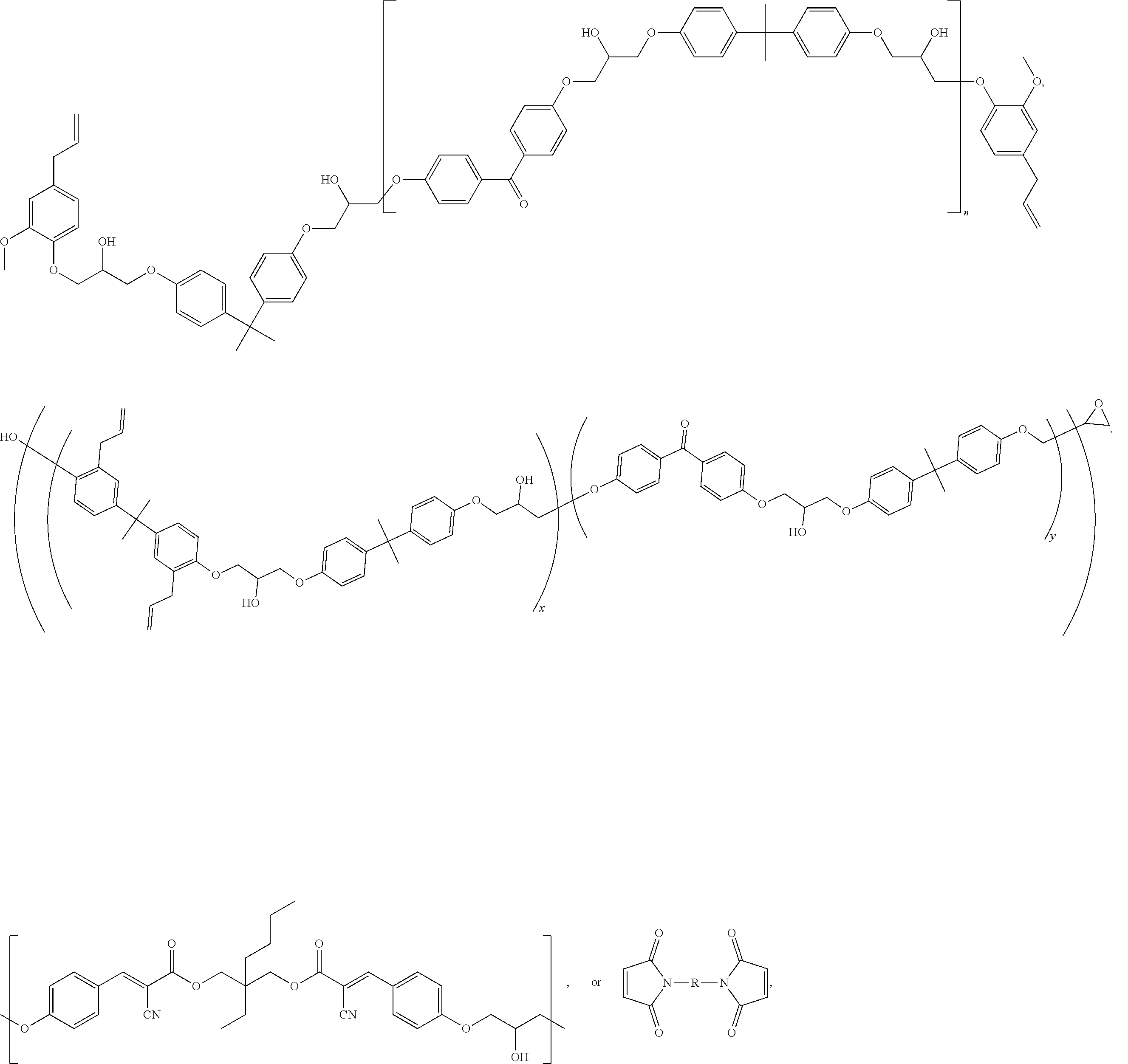
where R is chosen from substituted and unsubstituted alkyl groups, substituted and unsubstituted aromatic groups, or a combination of both.

7. The method of claim 1, wherein said first bonding layer comprises a thermoplastic material.

8. The method of claim 1, wherein said second bonding layer comprises a thermoset material.

9. The method of claim 1, wherein said first bonding layer comprises a conformal layer on said front surface.

10. The method of claim 9, wherein said front surface comprises a solder ball and said conformal layer is on said solder ball.

11. The method of claim 10, wherein said solder ball is connected to said front surface via an attachment point chosen from pillars, posts, pads, through-silicon vias, or conductive layers.

12. The method of claim 1, wherein said bonded first and second substrates comprise a stack, and further comprising, prior to said separating of said bonded first and second substrates, subjecting said stack to processing chosen from one or more of back-grinding, chemical-mechanical polishing, etching, metallizing, dielectric deposition, patterning, passivation, annealing, or redistribution layer formation.

13. The method of claim 1, wherein said first substrate further comprises a back surface, and further comprising, prior to said separating of said bonded first and second substrates:
(a) thinning the back surface of said first substrate to form a thinned back surface;
(b) bonding a first chip or first chiplet to said thinned back surface;
(c) optionally bonding a second chip or second chiplet to said first chip or first chiplet; and
(d) optionally repeating (c) one or more times to create a stacked structure.

14. A bonding method comprising bonding a first bonding layer and a second bonding layer together, wherein:
during said bonding a bond line adhesion promoter that is present in at least one of said first and second bonding layers covalently bonds with a component present in the other of said first and second bonding layers;
said first bonding layer is on a front surface of a first substrate;
said second bonding layer is on a first surface of a second substrate; and
at least one of said first and second substrates comprises a microelectronic substrate.

15. The method of claim 14, wherein said bond line adhesion promoter covalently bonds with said component through a functional group being chosen from imides, vinyls, allyls, hydroxys, epoxides, silicon hydrides, esters, alkynes, amines, ketone, aldehydes, amides, thiols, or mixtures thereof.

16. The method of claim 14, wherein:
said bond line adhesion promoter comprises a quantity of a functional group that covalently bonds with said component; and
said first bonding layer comprises one or both of a polymer or oligomer that is different from said bond line adhesion promoter, wherein said one or both of said polymer or oligomer comprises less than about 10% of said quantity of said functional group that covalently bonds with said component.

17. The method of claim 15, wherein said bond line adhesion promoter comprises said functional group.

18. The method of claim 15, wherein said bond line adhesion promoter comprises recurring monomeric units and about 50% or more of said recurring monomeric units comprises at least one of said functional groups.

19. The method of claim 14, wherein said first bonding layer comprises one or both of a polymer or oligomer that is different from said bond line adhesion promoter, wherein the total quantity of said one or both of said polymer or oligomer is about 30% to about 99.8% by weight, based on the weight of the first bonding layer taken as 100% by weight.

20. The method of claim 14, where said bond line adhesion promoter comprises a structure chosen from 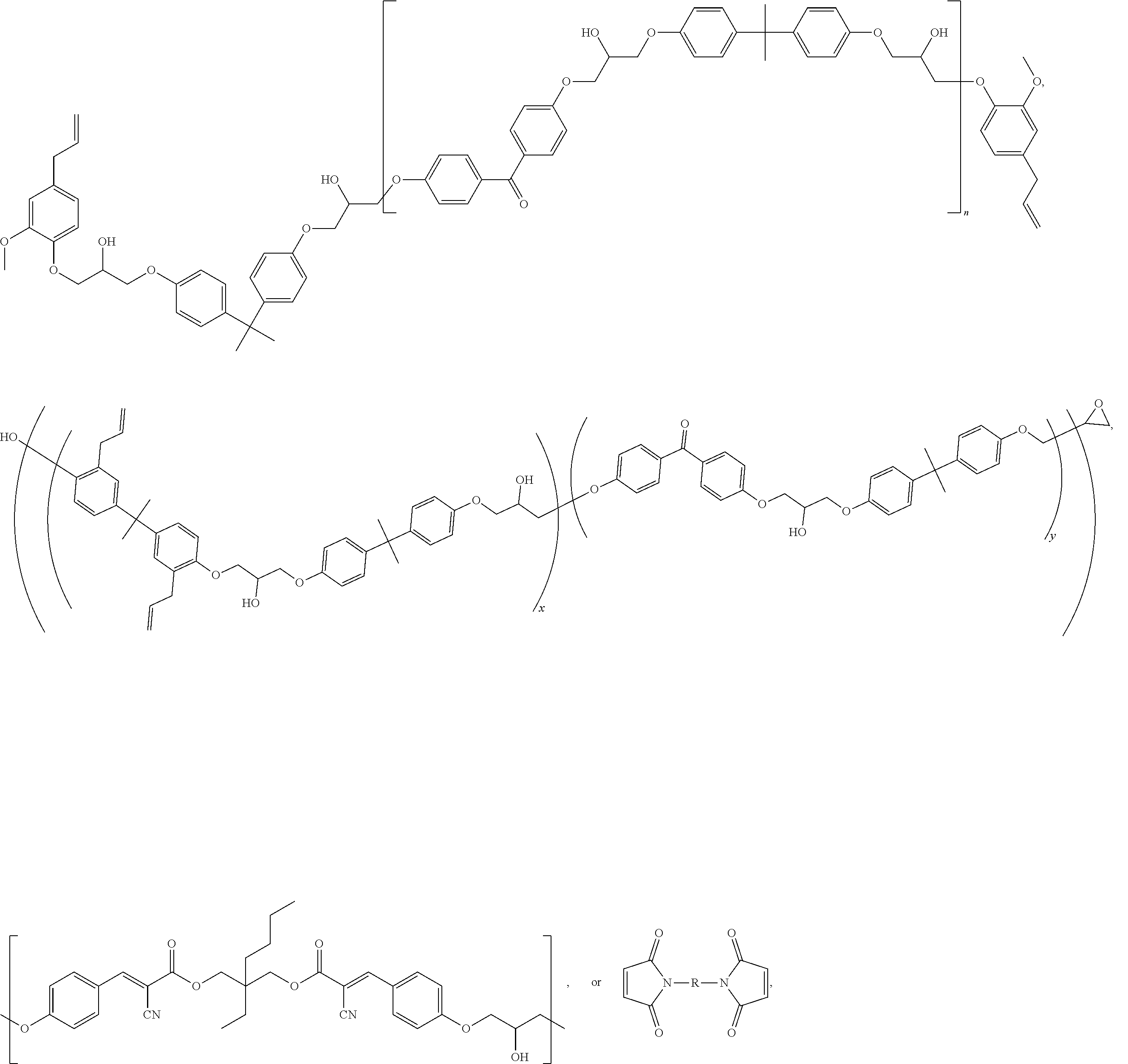
where R is chosen from substituted and unsubstituted alkyl groups, substituted and unsubstituted aromatic groups, or a combination of both.

21. The method of claim 14, wherein said first bonding layer comprises a thermoplastic material.

22. The method of claim 14, wherein said second bonding layer comprises a thermoset material.

23. The method of claim 14, further comprising, prior to said bonding, forming said first bonding layer on said front surface by conformally coating a composition including said bond line adhesion promoter on said front surface.

24. The method of claim 23, wherein said front surface comprises a solder ball and said first bonding layer conformally coats said front surface and solder ball.

25. The method of claim 14, wherein said bonding comprises pressing said first and second substrates together under heat and pressure so that said first and second bonding layers adhere to one another.

26. The method of claim 14, further comprising separating said bonded first and second substrates.

27. The method of claim 14, wherein said bonded first and second substrates comprise a stack, and further comprising subjecting said stack to processing chosen from one or more of back-grinding, chemical-mechanical polishing, etching, metallizing, dielectric deposition, patterning, passivation, annealing, or redistribution layer formation.

28. The method of claim 14, wherein said first substrate further comprises a back surface, and further comprising, prior to said separating of said bonded first and second substrates:
(a) thinning the back surface of said first substrate to form a thinned back surface;
(b) bonding a first chip or first chiplet to said thinned back surface;
(c) optionally bonding a second chip or second chiplet to said first chip or first chiplet; and
(d) optionally repeating (c) one or more times to create a stacked structure.

29. The method of claim 14, further comprising separating the bonded first and second substrates and using at least one of the first and second substrates to form a microelectronic structure.

30. A microelectronic structure comprising:
a first substrate comprising a front surface, there being a first bonding layer on said front surface;
a second substrate comprising a first surface, there being a second bonding layer on said first surface; and
at least one of said first and second bonding layers comprising a bond line adhesion promoter that is covalently bonded with a component present in the other of said first and second bonding layers.

31. The structure of claim 30, wherein said bond line adhesion promoter comprises a functional group that is covalently bonded with said component, said functional group being chosen from imides, vinyls, allyls, hydroxys, epoxides, silicon hydrides, esters, alkynes, amines, ketone, aldehydes, amides, thiols, or mixtures thereof.

32. The structure of claim 30, wherein:
said bond line adhesion promoter comprises a quantity of a functional group covalently bonded with said component; and
said first bonding layer comprises one or both of a polymer or oligomer that is different from said bond line adhesion promoter, wherein said one or both of said polymer or oligomer comprises less than about 10% of said quantity of said functional group covalently bonded with said component.

33. The structure of claim 31, wherein said bond line adhesion promoter comprises recurring monomeric units and about 50% or more of said recurring monomeric units comprises at least one of said functional groups bonded with said component.

34. The structure of claim 30, wherein said first bonding layer comprises one or both of a polymer or oligomer that is different from said bond line adhesion promoter, wherein the total quantity of said one or both of said polymer or oligomer is about 30% to about 99.8% by weight, based on the weight of the first bonding layer taken as 100% by weight.

35. The structure of claim 30, where said bond line adhesion promoter comprises a structure chosen from 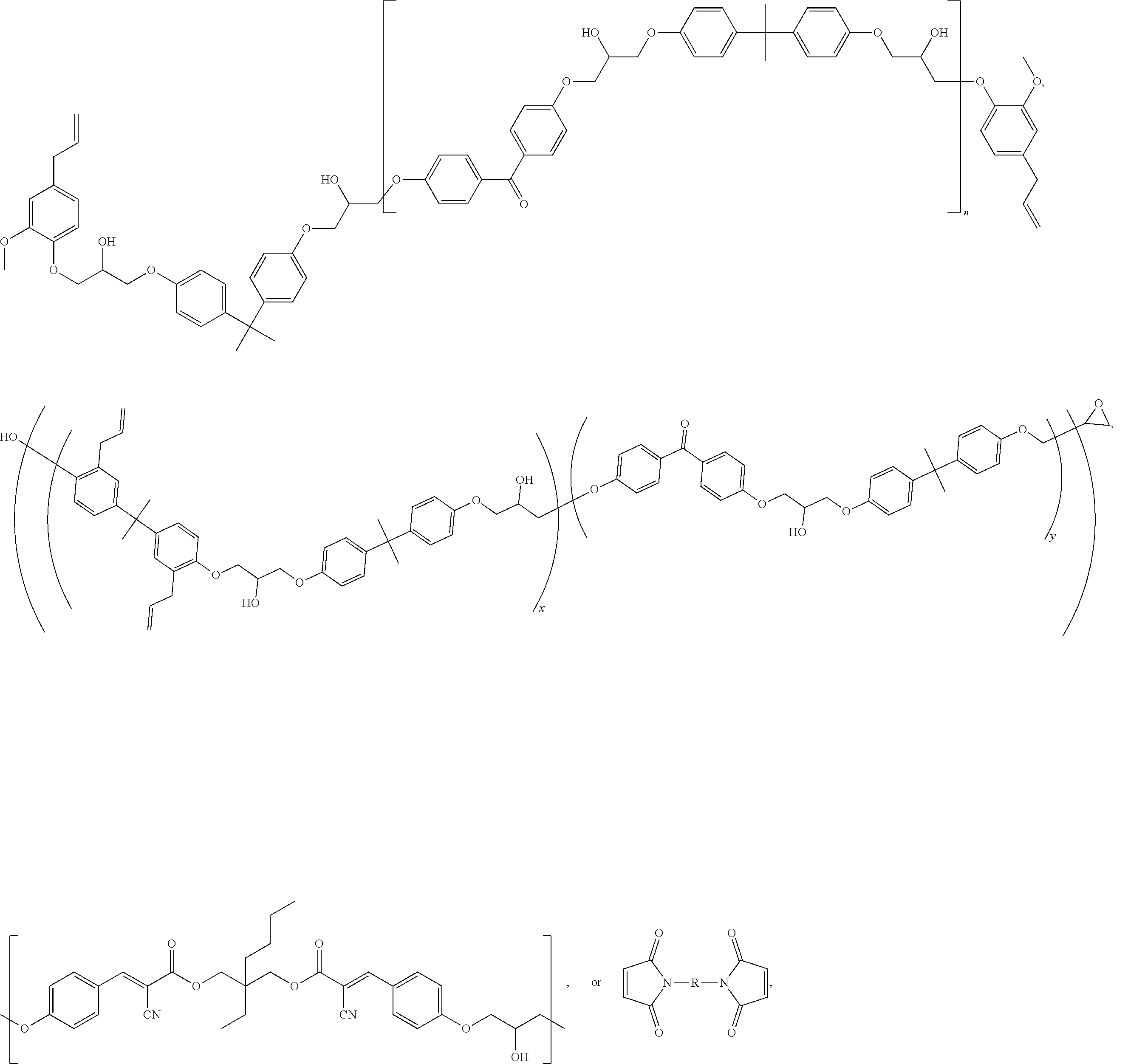
where R is chosen from substituted and unsubstituted alkyl groups, substituted and unsubstituted aromatic groups, or a combination of both.

36. The structure of claim 30, wherein said first bonding layer comprises a thermoplastic material.

37. The structure of claim 30, wherein said second bonding layer comprises a thermoset material.

38. The structure of claim 30, wherein said first bonding layer comprises a conformal layer on said front surface.

39. The structure of claim 38, wherein said front surface comprises a solder ball and said conformal layer is on said solder ball.

40. The structure of claim 39, wherein said solder ball is connected to said front surface via an attachment point chosen from pillars, posts, pads, through-silicon vias, or conductive layers.

41. The structure of claim 30, wherein:
said front surface comprises a plurality of solder balls;
said front surface presents areas that are free of solder balls;
said solder balls comprise respective outer surfaces; and
said conformal layer conformally coats said areas that are free of solder balls and conformally coat said respective outer surfaces.

42. The structure of claim 30, wherein said first substrate comprises silicon, SiGe, SiO₂, Si₃N₄, SiON, SiCO:H, tetramethyl silate and tetramethylcyclotetrasiloxane combinations, aluminum, tungsten, tungsten silicide, gallium arsenide, germanium, tantalum, tantalum nitride, Ti₃N₄, hafnium, HfO₂, ruthenium, indium phosphide, or glass.
